(19) United States
(12) Patent Application Publication
(10) Pub. No.: US 2025/0169083 A1
(43) Pub. Date: May 22, 2025

(54) SEMICONDUCTOR DEVICE

(71) Applicant: Samsung Electronics Co., Ltd., Suwon-si (KR)

(72) Inventors: IN JUNG, Suwon-si (KR); JONGHYUK KIM, Suwon-si (KR); BOK-YEON WON, Suwon-si (KR)

(21) Appl. No.: 18/944,349

(22) Filed: Nov. 12, 2024

(30) Foreign Application Priority Data
Nov. 17, 2023 (KR) 10-2023-0159764

(51) Int. Cl. H10B 80/00; H01L 23/00; H01L 25/065; H01L 25/18

(52) U.S. Cl. CPC H10B 80/00; H01L 24/08; H01L 25/0657; H01L 25/18; H01L 2224/08145; H01L 2924/1431; H01L 2924/1436

(57) ABSTRACT

A semiconductor device including: a substrate having a portion in a cell array region and a portion in a peripheral circuit region; a peripheral circuit structure including a peripheral circuit, and peripheral circuit wiring connected to the peripheral circuit; and a cell array structure, wherein the cell array structure in the cell array region includes a plurality of bit lines extending in a first direction, a plurality of word lines extending on the plurality of bit lines in a second direction, an active pattern disposed between a first word line and a second word line, a cell landing pad connected to the active pattern, and a cell capacitor, and the cell array structure in the peripheral circuit region includes a conductive pad disposed at the same level as an end of the cell capacitor, and a lower conductive contact plug connecting the conductive pad and the peripheral circuit structure.

### CROSS-REFERENCE TO RELATED APPLICATION

This application claims priority to and the benefit of Korean Patent Application No. 10-2023-0159764 filed in the Korean Intellectual Property Office on Nov. 17, 2023, the entire contents of which are incorporated herein by reference.

### BACKGROUND

### 1. Field

The present disclosure relates to a semiconductor device.

### 2. Description of the Related Art

There has been a need for a semiconductor memory device with increased integration to meet the excellent performance and low price demanded by a consumer. The increased integration of the semiconductor memory device may be beneficial because the amount of integration is an important factor in determining a price of the product.

The integration of a two-dimensional or planar semiconductor memory device may be mainly determined by an area of a unit memory cell and thus the amount of integration is greatly affected by a level of fine pattern formation technology. However, ultra-expensive equipment may be required to implement the fine pattern to achieve the level of integration demanded and the two-dimensional semiconductor memory device may thereby have the integration increased, but the amount of integration achieved in the two-dimensional or planar semiconductor memory device is still limited.

Alternatively, it is possible to utilize a region other than a cell region such as a region surrounding the cell region to improve the integration of the semiconductor memory device and simultaneously improve driving ability of the semiconductor memory device. For example, it is possible to dispose wiring in the region surrounding the cell region to improve the integration of the semiconductor memory device and utilize the wiring disposed in the surrounding region to thus improve current driving ability of the semiconductor memory device.

### SUMMARY

The inventive concept of the present disclosure may provide a semiconductor device with improved reliability and productivity.

According to an embodiment, provided is a semiconductor device including: a substrate having a portion in a cell array region and a portion in a peripheral circuit region; a peripheral circuit structure including a peripheral circuit disposed on the substrate, and peripheral circuit wiring connected to the peripheral circuit; and a cell array structure disposed on the peripheral circuit structure, wherein the cell array structure in the cell array region includes a plurality of bit lines disposed on the peripheral circuit structure and extending in a first direction, a plurality of word lines extending on the plurality of bit lines in a second direction that is different than the first direction, an active pattern disposed between a first word line and a second word line of the plurality of word lines, a cell landing pad connected to the active pattern, and a cell capacitor disposed on the cell landing pad, and the cell array structure in the peripheral circuit region includes at least one conductive pad including the same material as the cell capacitor and disposed with a lower surface of the conductive pad at the same level as a lower end of the cell capacitor, and a lower conductive contact plug connecting the conductive pad and the peripheral circuit structure to each other.

According to another embodiment, provided is a semiconductor device including: a substrate having a portion in a cell array region and a portion in a peripheral circuit region; a peripheral circuit structure including a peripheral circuit disposed on the substrate, and peripheral circuit wiring connected to the peripheral circuit; and a cell array structure disposed on the peripheral circuit structure, wherein the cell array structure in the cell array region includes a plurality of bit lines disposed on the peripheral circuit structure and extending in a first direction, a plurality of word lines extending on the plurality of bit lines in a second direction that is different than the first, an active pattern disposed between a first word line and a second word line of the plurality of word lines, a cell landing pad connected to the active pattern, and a cell capacitor disposed on the cell landing pad, wherein the cell array structure in the peripheral circuit region includes a peripheral landing pad including the same material as the cell landing pad, and disposed at the same level as the cell landing pad, at least one peripheral capacitor disposed at the same level as the cell capacitor, and disposed on the peripheral landing pad, an upper wiring disposed on the peripheral capacitor, an upper conductive contact plug connecting the peripheral capacitor and the upper wiring to each other, and a lower conductive contact plug connecting the peripheral landing pad and the peripheral circuit structure to each other, and wherein the peripheral capacitor includes a peripheral lower electrode connected to the peripheral landing pad, a peripheral upper electrode covering the peripheral lower electrode, and a peripheral dielectric film disposed between the peripheral lower electrode and the peripheral upper electrode.

According to still another embodiment, provided is a semiconductor device including: a substrate having a first portion in a cell array region and a second portion in a peripheral circuit region; a peripheral circuit structure including a peripheral circuit disposed on the substrate, and peripheral circuit wiring connected to the peripheral circuit; and a cell array structure disposed on the peripheral circuit structure, wherein the cell array structure in the cell array region includes a plurality of bit lines disposed on the peripheral circuit structure and extending in a first direction, a plurality of word lines extending on the plurality of bit lines in a second direction that is different than the first, an active pattern disposed between a first word line and a second word line of the plurality of word lines, a cell landing pad connected to the active pattern, and a cell capacitor disposed on the cell landing pad, wherein the cell array structure in the peripheral circuit region includes a first conductive pad and a second conductive pad disposed at the same level as an end of the cell capacitor, and an upper insulation layer covering the first conductive pad and the second conductive pad, and disposed between the first conductive pad and the second conductive pad, each of the first conductive pad and the second conductive pad has a planar line shape on a plane, the first conductive pad and the second conductive pad are arranged alternately with each other for the conductive pads to at least partially overlap each other, and a first peripheral sub-capacitor is configured to the first conductive pad, the second conductive pad, and the upper insulation layer.

According to the embodiments, the semiconductor device may have the improved driving ability by further including the wiring, the metal-insulator-metal (MIM) capacitor, and the decoupling capacitor in the peripheral circuit region disposed around the cell array region, each of which may include the same material as a component disposed in the cell array region.

### BRIEF DESCRIPTION OF THE DRAWINGS

FIG. 1 is a plan view of a semiconductor device according to an embodiment.

FIG. 2 is a cross-sectional view showing a cross-section taken along lines A-A′ and B-B′ of FIG. 1.

FIG. 3 is a cross-sectional view showing a cross-section taken along line C-C′ of FIG. 1.

FIGS. 4 to 6, 8, 9, and 12 to 16 are views showing a cross-section of a semiconductor device according to some embodiments.

FIGS. 7, 10, and 11 are plan views of the semiconductor device according to some embodiments.

### DETAILED DESCRIPTION

Hereinafter, embodiments of the present disclosure will be described in detail with reference to the accompanying drawings so that those skilled in the art may easily practice the inventive concept. However, the inventive concept may be implemented in various different forms and is not limited to the embodiments described herein.

In the drawings, like numbers refer to like components throughout. Though the different figures show variations of embodiments, these figures are not necessarily intended to be mutually exclusive from each other. Rather, as will be seen from the context of the detailed description below, certain features depicted and described in different figures can be combined with other features from other figures to result in various embodiments, when taking the figures and their description as a whole into consideration. In the description of the drawing, components that are the same or similar in multiple drawings may not be described or may be only briefly referenced when the same or similar component was described in reference to an earlier drawing.

In addition, the size and thickness of each component shown in the accompanying drawings are arbitrarily shown for convenience of explanation, and therefore, the inventive concept is not necessarily limited to contents shown in the drawings. The thicknesses are exaggerated in the drawings in order to clearly represent several layers and regions. In addition, the thicknesses of some layers and regions are exaggerated in the drawings for convenience of explanation.

In addition, when an element such as a layer, a film, a region or a substrate is referred to as being “on” or “above” another element, the element may be “directly on” another element or may have other elements interposed therebetween. On the other hand, when an element is referred to as being “directly on” another element, there is no third element or other elements interposed therebetween. In addition, when an element is referred to as being “on” or “above” a reference element, the element may be disposed below the reference element when the embodiment is rotated to a different orientation than shown in the figures. As such, the use of the term above may not be in reference to a gravitational direction but may instead be specific to the drawing being described, and may not necessarily be “on” or “above” the reference element in an opposite direction of gravity.

In addition, throughout the specification, when an element “includes” another component, it is to be understood that the element may further include a third component rather than excluding the third component, unless explicitly described to the contrary. As used herein, the singular forms “a”, “an” and “the” are intended to include the plural forms as well, unless the context clearly indicates otherwise. As used herein, the term “and/or” includes any and all combinations of one or more of the associated listed items and may be abbreviated as “/”.

Further, throughout the specification, an expression “on the plane” may indicate a case where a target is viewed from above as indicated by Z direction in a drawing, and an expression “on the cross-section” may indicate a case where a cross-section of a target taken along a vertical direction, which may be a vertical plane, is viewed from its side (e.g., orthogonal to the cross-section).

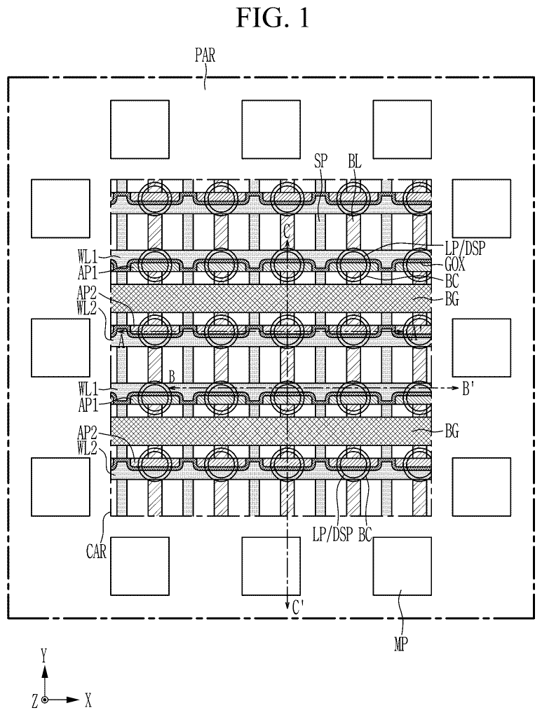

Hereinafter, the description describes a semiconductor device according to an embodiment with reference to FIGS. 1 to 3.

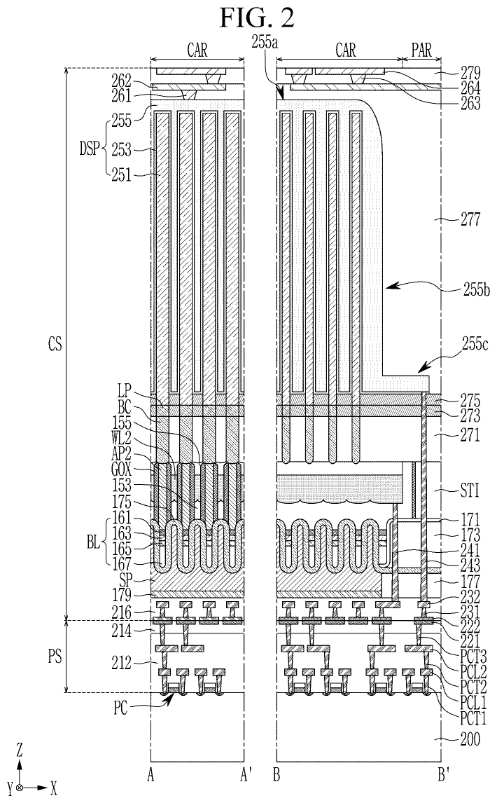

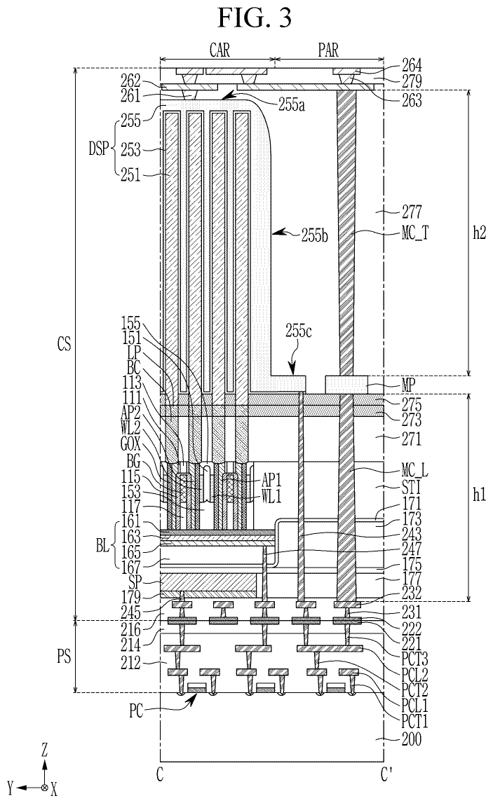

FIG. 1 is a plan view of a semiconductor device according to an embodiment. FIG. 2 is a cross-sectional view showing a cross-section taken along lines A-A′ and B-B′ of FIG. 1. FIG. 3 is a cross-sectional view showing a cross-section taken along line C-C′ of FIG. 1.

The semiconductor device according to the embodiments of the inventive concept may include a memory cell including a vertical channel transistor VCT. However, this configuration is an example, the semiconductor device according to the embodiments of the inventive concept is not limited thereto and may be changed in various ways. For example, the semiconductor device according to the embodiments of the inventive concept may be a dynamic random access memory (DRAM).

Referring to FIGS. 1 to 3, a semiconductor device according to some embodiments may include a substrate 200, a peripheral circuit structure PS disposed on the substrate 200, and a cell array structure CS disposed on the peripheral circuit structure PS.

The semiconductor device may have a cell array region CAR and a peripheral circuit region PAR. The cell array region CAR and the peripheral circuit region PAR may be horizontal regions of the semiconductor device that extend vertically to include portions of the substrate 200 and elements disposed on the substrate. A first portion of the substrate 200 may be disposed in the cell array region CAR and a second portion of the substrate may be disposed in the peripheral circuit region PAR defined laterally around the cell array region CAR.

For example, the peripheral circuit region PAR may be disposed to be adjacent to the cell array region CAR and surround the cell array region CAR. However, arrangements and relationships between the cell array region CAR and the peripheral circuit region PAR are not limited thereto and may be changed in various ways.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim).

A cell capacitor DSP may be disposed in the cell array region CAR, and a plurality of conductive pads MP, a metal-insulator-metal (MIM) capacitor, a decoupling capacitor, or the like, which may each include the same material as that of an electrode component disposed in the cell array region CAR may be disposed in the peripheral circuit region PAR. The details of these components are described below.

The substrate 200 may be a silicon substrate or may be formed of and/or include another material such as silicon germanium, indium antimonide, lead tellurium compound, indium arsenide, indium phosphide, gallium arsenide, or gallium antimonide. However, the substrate 200 is not limited thereto in embodiments of the inventive concept, and materials included in the substrate 200 may be changed in various ways.

The peripheral circuit structure PS may be disposed on the substrate 200. The peripheral circuit structure PS may be disposed between the substrate 200 and the cell array structure CS. The peripheral circuit structure PS may be disposed across the cell array region CAR and the peripheral circuit region PAR. For example, a portion of the peripheral circuit structure PS may be disposed in the cell array region CAR, and the other portion may be disposed in the peripheral circuit region PAR.

The peripheral circuit structure PS may include a peripheral circuit PC, peripheral contact plugs PCT1, PCT2, and PCT3, peripheral circuit wirings PCL1 and PCL2, a peripheral circuit insulation layer 212, a lower bonding insulation layer 214, and a lower bonding pad 221.

The peripheral circuit PC may be, for example, a sensing transistor, a transfer transistor, or a driving transistor. However, a type of the transistor of the peripheral circuit PC may be variously changed based on the design and disposition of the semiconductor device.

The peripheral circuit structure PS may be disposed on the substrate 200. The peripheral circuit PC may include a peripheral circuit gate insulation layer and a peripheral circuit conductive pattern that are sequentially stacked on the substrate 200.

The peripheral circuit gate insulation layer may be formed of and/or include silicon oxide, silicon nitric oxide, a high-k material with a higher dielectric constant than silicon oxide, or a combination thereof. The high-k material may include, for example, at least one of metal oxide, metal nitric oxide, metal silicon oxide, and metal silicon nitric oxide, and is not limited thereto in embodiments of the inventive concept.

The peripheral circuit conductive pattern may be formed of and/or include a conductive material. For example, the peripheral circuit conductive pattern may be formed of and/or include at least one of a doped semiconductor material, conductive metal nitride, conductive metal silicon nitride, metal carbonitride, conductive metal silicide, conductive metal oxide, a two-dimensional (2D) material, and a metal.

In some embodiments, the 2D material may be a metallic material and/or a semiconductor material. The 2D material may include a 2D allotrope or a 2D compound, include, for example, at least one of graphene, molybdenum disulfide (MoS₂), molybdenum diselenide (MoSe₂), tungsten diselenide (WSe₂), and tungsten disulfide (WS₂), and is not limited thereto in embodiments of the inventive concept.

Although not shown in FIGS. 1 to 3, the semiconductor device may further include a peripheral circuit spacer disposed on a side surface of the peripheral circuit PC. The peripheral circuit spacer may be formed of and/or include an insulation material. For example, the peripheral circuit spacer may include a silicon oxide film, a silicon nitride film, a silicon oxynitride film, and/or a low-k dielectric film.

The peripheral circuit insulation layer 212 may cover the peripheral circuit PC. For example, the peripheral circuit insulation layer 212 may cover the side and upper surfaces of the peripheral circuit PC. The peripheral circuit insulation layer 212 may be formed of and/or include an insulation material which may be the same insulation material described previously. For example, the peripheral circuit insulation layer 212 may include the silicon oxide film, the silicon nitride film, the silicon oxynitride film, and/or the low-k dielectric film. However, the peripheral circuit insulation layer 212 is not limited thereto in embodiments of the inventive concept.

The first peripheral contact plug PCT1, the second peripheral contact plug PCT2, the first peripheral circuit wiring PCL1, and the second peripheral circuit wiring PCL2 may be disposed in the peripheral circuit insulation layer 212.

The first peripheral circuit wiring PCL1 may be electrically connected to the peripheral circuit PC through the first peripheral contact plug PCT1. For example, the first peripheral circuit wiring PCL1 may be electrically connected to a source/drain region disposed on at least one side of the peripheral circuit PC through the first peripheral contact plug PCT1. The first peripheral circuit wiring PCL1 and the second peripheral circuit wiring PCL2 may be connected to each other by the second peripheral contact plug PCT2.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

As used herein, items described as being “electrically connected” are configured such that an electrical signal can be passed from one item to the other. Therefore, a passive electrically conductive component (e.g., a wire, pad, internal electrical line, etc.) physically connected to a passive electrically insulative component (e.g., a prepreg layer of a printed circuit board, an electrically insulative adhesive connecting two devices, an electrically insulative underfill or mold layer, etc.) is not electrically connected to that component. Moreover, items that are “directly electrically connected,” to each other are electrically connected through one or more passive elements, such as, for example, wires, pads, internal electrical lines, through vias, etc. As such, directly electrically connected components do not include components electrically connected through active elements, such as transistors or diodes. Directly electrically connected elements may be directly physically connected and directly electrically connected.

FIGS. 1 to 3 show that the peripheral circuit insulation layer 212 is made of a single layer, but embodiments of the inventive concept are not limited thereto. The peripheral circuit insulation layer 212 may be made of multiple layers including the same material as each other and/or different materials from each other. When the peripheral circuit insulation layer 212 is made of the multiple layers, the first peripheral contact plug PCT1, the second peripheral contact plug PCT2, the first peripheral circuit wiring PCL, and the second peripheral circuit wiring PCL2 may respectively be disposed in different layers.

The lower bonding insulation layer 214 may be disposed on the peripheral circuit insulation layer 212. The lower bonding insulation layer 214 may be formed of and/or include the insulation material. For example, the lower bonding insulation layer 214 may be formed of and/or include silicon carbonitride (SiCN). However, a material included in the lower bonding insulation layer 214 is not limited thereto and may be changed in various ways.

The third peripheral contact plug PCT3 may be disposed in the peripheral circuit insulation layer 212 and the lower bonding insulation layer 214. For example, the third peripheral contact plug PCT3 may have a portion disposed in the peripheral circuit insulation layer 212 and the other portion disposed in the lower bonding insulation layer 214.

The lower bonding pad 221 may be disposed in the lower bonding insulation layer 214. The lower bonding pad 221 may be electrically connected to the second peripheral circuit wiring PCL2 through the third peripheral contact plug PCT3.

Accordingly, the lower bonding pad 221 may be electrically connected to the peripheral circuit PC through the second peripheral circuit wiring PCL2, the second peripheral contact plug PCT2, the first peripheral circuit wiring PCL1, and the first peripheral contact plug PCT1. However, a connection method between the lower bonding pad 221 and the peripheral circuit PC is not limited thereto and may be changed in various ways.

The cell array structure CS may be disposed on the peripheral circuit structure PS. For example, the cell array structure CS may overlap the peripheral circuit structure PS in a third direction Z which is a direction vertical to the peripheral circuit structure PS. However, an arrangement relationship between the cell array structure CS and the peripheral circuit structure PS is not limited thereto and may be changed in various ways. For example, the cell array structure CS may be disposed to be adjacent to the peripheral circuit structure PS in a horizontal direction. As another example, the cell array structure CS May be disposed under the peripheral circuit structure PS and may overlap the peripheral circuit structure PS in the third direction Z which is the vertical direction.

Hereinafter, the description is provided based on an example in which the cell array structure CS is disposed on the peripheral circuit structure PS.

In an embodiment, the peripheral circuit structure PS and the cell array structure CS may be a bonded semiconductor device having a chip-to-chip (C2C) structure bonded by a wafer bonding method (e.g., hybrid bonding). However, a method of bonding the peripheral circuit structure PS with the cell array structure CS is not limited thereto and may be changed in various ways.

In an embodiment, the peripheral circuit structure PS may include a first surface and second surface opposing the first surface. The first surface of the peripheral circuit structure PS may be its surface facing the cell array structure CS, and the second surface of the peripheral circuit structure PS may be a surface facing away from the cell array structure CS. Here, the first surface of the peripheral circuit structure PS may indicate a front side of the peripheral circuit structure PS, and the second surface of the peripheral circuit structure PS may indicate a back side of the peripheral circuit structure PS.

In addition, the cell array structure CS may include a first surface and a second surface opposing each other. The first surface of the cell array structure CS may be its surface facing the peripheral circuit structure PS, and the second surface of the cell array structure CS may be a surface facing away from the peripheral circuit structure PS.

In an embodiment, a surface of the peripheral circuit structure PS that is adjacent to the cell array structure CS may be its bonding surface with the cell array structure CS. In addition, a surface of the cell array structure CS that is adjacent to the peripheral circuit structure PS may be its bonding surface with the peripheral circuit structure PS. For example, a surface of the peripheral circuit structure PS and a surface of the cell array structure CS may be the bonding surfaces of the peripheral circuit structure PS and the cell array structure CS. Here, a surface of the peripheral circuit structure PS and a surface of the cell array structure CS may be bonded to each other by the hybrid bonding.

In detail, the cell array structure CS may include an upper bonding insulation layer 216 disposed with a portion in contact with the peripheral circuit structure PS. The upper bonding insulation layer 216 may be formed of and/or include the same material as the lower bonding insulation layer 214 disposed on the peripheral circuit structure PS described above and may be disposed on the lower bonding insulation layer 214.

An upper bonding pad 222 may be disposed in the upper bonding insulation layer 216 disposed on the cell array structure CS. The upper bonding pad 222 disposed in the upper bonding insulation layer 216 may be in contact with and bonded to the lower bonding pad 221 disposed in the lower bonding insulation layer 214 to form metal bonding therebetween. For example, an upper surface of the lower bonding pad 221 and a lower surface of the upper bonding pad 222 may be in contact with each other. For example, the lower bonding pad 221 and upper bonding pad 222 may each be disposed at a boundary surface of the peripheral circuit structure PS and the cell array structure CS and may be in contact with each other.

A lower contact plug 231 and a lower wiring 232 connected to the lower contact plug 231 may be disposed in the upper bonding insulation layer 216. The lower wiring 232 may be connected to a component disposed in the cell array structure CS and the lower contact plug 231 may electrically connect the upper bonding pad 222 and the lower wiring 232 to each other.

FIGS. 1 to 3 show that the lower contact plug 231 and the lower wiring 232 are disposed in the upper bonding insulation layer 216, but the inventive concept is not limited thereto. For example, the lower contact plug 231 and the lower wiring 232 may be disposed in an insulation layer separate from the upper bonding insulation layer 216 and connected to the upper bonding pad 222 disposed in the upper bonding insulation layer 216.

The upper bonding insulation layer 216 disposed in the cell array structure CS and the lower bonding insulation layer 214 disposed in the peripheral circuit structure PS may be bonded to each other, thus forming a bonding insulation layer. For example, an upper surface of the lower bonding insulation layer 214 and the upper surface of the lower bonding pad 221 may form one surface of the peripheral circuit structure PS, and a lower surface of the upper bonding insulation layer 216 and the lower surface of the upper bonding pad 222 may form one surface of the cell array structure CS. For example, the upper surface of the lower bonding insulation layer 214 and the lower surface of the upper bonding insulation layer 216 may partially form the bonding surfaces of the peripheral circuit structure PS and the cell array structure CS.

Accordingly, the lower bonding pad 221 of the peripheral circuit structure PS and the upper bonding pad 222 of the cell array structure CS may be bonded to each other, thereby providing an electrical connection path between the peripheral circuit structure PS and the cell array structure CS. For example, the lower wiring 232 connected to the component included in the cell array structure CS may be connected to the peripheral circuit PC and/or the peripheral circuit wirings PCL1 and PCL2 included in the peripheral circuit structure PS by the lower bonding pad 221 and the upper bonding pad 222.

Each of the peripheral contact plugs PCT1, PCT2, and PCT3, and the peripheral circuit wirings PCL1 and PCL2, which are disposed in the peripheral circuit structure PS, and the lower contact plug 231 and the lower wiring 232 which are disposed in the cell array structure CS may be formed of and/or include a conductive material. For example, the conductive material may include aluminum (Al), tungsten (W), titanium (Ti), copper (Cu), tantalum (Ta), or the like.

The lower bonding pad 221 disposed in the peripheral circuit structure PS and the upper bonding pad 222 disposed in the cell array structure CS may be formed of and/or include the same conductive material as one another. For example, the conductive material of the bonding pads may include copper (Cu).

As described above, the cell array structure CS may include the memory cell including the vertical channel transistor VCT.

In an embodiment, the cell array structure CS disposed in the cell array region CAR may include bit lines BL, a shielding pattern SP, active patterns AP1 and AP2, word lines WL1 and WL2, a back gate electrode BG, a buried contact BC, a cell landing pad LP, and the cell capacitor DSP The cell array structure CS disposed in the peripheral circuit region PAR may include the plurality of conductive pads MP, an upper conductive contact plug MC_T, and a lower conductive contact plug MC_L, which are each connected to a conductive pad of the plurality of conductive pads MP.

The bit lines BL may be parallel to each other and spaced apart in a first direction X and may extend in a second direction Y intersecting a first direction X. The bit lines BL may be disposed on the substrate 200 while being spaced apart from each other in the first direction.

Although not shown in FIG. 1, in some embodiments, the bit lines BL may extend in the second direction Y to reach the peripheral circuit region PAR from the cell array region CAR. Accordingly, an end of a bit line BL may be disposed in the peripheral circuit region PAR.

Each of the bit lines BL may include a polysilicon layer 161, a first metal layer 163, a second metal layer 165, and a bit line hard mask layer 167, which are sequentially stacked.

The polysilicon layer 161 may be formed of and/or include polysilicon doped with impurities, and each of the first metal layer 163 and the second metal layer 165 may be formed of and/or include a conductive material. For example, the first metal layer 163 may be formed of and/or include conductive metal nitride (e.g., titanium nitride, or tantalum nitride), and the second metal layer 165 may be formed of and/or be formed of and/or include the metal (e.g., tungsten, titanium, or tantalum). In addition, at least one of the first metal layer 163 and the second metal layer 165 may be formed of and/or include metal silicide such as titanium silicide, cobalt silicide, or nickel silicide. However, a material included in the first metal layer 163 or the second metal layer 165 is not limited thereto and may be changed in various ways.

The bit line hard mask layer 167 may be formed of and/or include an insulation material such as silicon nitride or silicon nitric oxide.

In some embodiments, the bit lines BL may be formed of and/or include a 2D or three-dimensional (3D) material, and may include, for example, graphene which is a carbon-based 2D material, a carbon nanotube which is the 3D material, or a combination thereof.

The bit lines BL may be disposed to be adjacent to the peripheral circuit structure PS. Disposing the bit lines BL adjacent to the peripheral circuit structure PS reduces the electrical connection path between the bit line BL and the peripheral circuit PC.

The shielding pattern SP may be disposed between the peripheral circuit structure PS and the bit line BL. The shielding pattern SP may have portions disposed between the bit lines BL and may extend in the second direction Y. For example, the shielding patterns SP may be arranged alternately with the bit line BL in the first direction X.

The semiconductor device according to an embodiment may further include a spacer insulation layer 175 defining a gap region between bit lines BL that are adjacent to each other.

The spacer insulation layer 175 may have a substantially uniform thickness and may be disposed conformally on the bit lines BL. The spacer insulation layer 175 may cover the two side surfaces and upper surfaces of each of the bit lines BL. The spacer insulation layer 175 may define each gap region between the bit lines BL. The gap region of the spacer insulation layer 175 may extend in the second direction Y to be parallel to the bit line BL.

The shielding pattern SP may be made of a conductive material, and the shielding pattern SP may be formed of and/or include, for example, a metal material such as tungsten (W), titanium (Ti), nickel (Ni), or cobalt (Co). As another example, the shielding pattern SP may be formed of and/or include a conductive 2D material such as graphene.

The spacer insulation layer 175 may include, for example, a silicon oxide film, a silicon nitride film, a silicon nitric oxide film, and/or a low-k dielectric film.

The shielding pattern SP may be disposed on the spacer insulation layer 175 and disposed in the gap region of the spacer insulation layer 175. For example, the shielding pattern SP may fill the gap region of the spacer insulation layer 175.

As shown in FIG. 2, the shielding pattern SP may include a line part (i.e., portion) disposed between the neighboring (i.e., adjacent) bit lines BL and a connection part (i.e., portion) commonly connecting the line parts to each other.

In detail, the line part of the shielding pattern SP may be disposed between the bit lines BL and disposed in the gap region of the spacer insulation layer 175. Accordingly, the line part of the shielding pattern SP and the side surface of the bit line BL may be spaced apart from each other in the first direction X while having the spacer insulation layer 175 therebetween.

FIG. 2 shows that a height of the bit lines BL in the third direction Z is smaller than a height of the line part of the shielding pattern SP in the third direction Z, but embodiments are not limited thereto. The height of the bit lines BL in the third direction Z and the height of the line part of the shielding pattern SP in the third direction Z may be the same or substantially the same as each other, or the height of the bit lines BL in the third direction Z may be greater than the height of the line part of the shielding pattern SP in the third direction Z.

Terms such as “same,” “equal,” “planar,” or “coplanar,” as used herein when referring to orientation, layout, location, shapes, sizes, compositions, amounts, or other measures do not necessarily mean an exactly identical orientation, layout, location, shape, size, composition, amount, or other measure, but are intended to encompass nearly identical orientation, layout, location, shapes, sizes, compositions, amounts, or other measures within acceptable variations that may occur, for example, due to manufacturing processes. The term “substantially” may be used herein to emphasize this meaning, unless the context or other statements indicate otherwise. For example, items described as “substantially the same,” “substantially equal,” or “substantially planar,” may be exactly the same, equal, or planar, or may be the same, equal, or planar within acceptable variations that may occur, for example, due to manufacturing processes.

The connection part of the shielding pattern SP may be connected to the line part and integrated with the line part (i.e., may be a single component). The connection part of the shielding pattern SP may be disposed on the line part and may connect the line parts, each of which is disposed between the adjacent bit lines BL, to each other. However, the inventive concept is not limited thereto, and in some embodiments, the line part and connection part of the shielding pattern SP may be separate components.

Although not shown in FIG. 1, the connection part of the shielding pattern SP may be disposed in the cell array region CAR and the peripheral circuit region PAR. For example, the connection part of the shielding pattern SP may extend from the cell array region CAR to the peripheral circuit region PAR. Accordingly, an end of the connection part of the shielding pattern SP may be disposed in the peripheral circuit region PAR.

The semiconductor device according to an embodiment may further include a shielding capping pattern 179 disposed on the shielding pattern SP, a first lower insulation layer 177 disposed between the spacer insulation layer 175 and the upper bonding insulation layer 216, a second lower insulation layer 173 disposed on the spacer insulation layer 175, a bit line etch stop layer 171 disposed between the bit line BL and the spacer insulation layer 175, and a cell region element isolation layer STI disposed on the second lower insulation layer 173.

The shielding capping pattern 179 may be disposed on the shielding pattern SP, and the shielding capping pattern 179 may be in contact with the upper bonding insulation layer 216. The shielding capping pattern 179 may have a substantially uniform thickness and cover the shielding pattern SP.

The first lower insulation layer 177 may be disposed on the upper bonding insulation layer 216. An upper surface of the first lower insulation layer 177 may be in contact with the spacer insulation layer 175, and a side surface of the first lower insulation layer 177 may be in contact with an end of the shielding pattern SP and an end of the shielding capping pattern 179. For example, the first lower insulation layer 177 may cover the end of the shielding pattern SP and the end of the shielding capping pattern 179.

The second lower insulation layer 173 may be disposed on the spacer insulation layer 175. The side surface of the second lower insulation layer 173 may face the end of the bit line BL.

The bit line etch stop layer 171 may be disposed between the bit lines BL and the spacer insulation layer 175. The bit line etch stop layer 171 may extend along the upper and side surfaces of the bit lines BL. The bit line etch stop layer 171 may be disposed on the second lower insulation layer 173 and extend along the upper and side surfaces of the second lower insulation layer 173.

The cell region element isolation layer STI may be disposed on the second lower insulation layer 173. A portion of the bit line etch stop layer 171 may be disposed between the cell region element isolation layer STI and the second lower insulation layer 173. A portion of the cell region element isolation layer STI may overlap the bit line etch stop layer 171 in the third direction Z which is the direction vertical to the bit lines BL. The bit line etch stop layer 171 May overlap the cell region element isolation layer STI in the third direction Z.

Each of the shielding capping pattern 179, the first lower insulation layer 177, the second lower insulation layer 173, the bit line etch stop layer 171, and the cell region element isolation layer STI may include a silicon oxide film, a silicon nitride film, a silicon nitric oxide film, and/or a low-k dielectric film. For example, the shielding capping pattern 179 and the bit line etch stop layer 171 may be formed of and/or include silicon nitride, and the first lower insulation layer 177, the second lower insulation layer 173, and the cell region element isolation layer STI may be formed of and/or include silicon oxide.

The semiconductor device according to an embodiment may further include a shielding contact plug 245 and a bit line contact plug 247.

The shielding pattern SP may be electrically connected to the upper bonding pad 222 through the shielding contact plug 245 penetrating through the upper bonding insulation layer 216 and the shielding capping pattern 179. For example, the shielding pattern SP may be electrically connected to the upper bonding pad 222 through the lower wiring 232 and the lower contact plug 231, which are connected to the shielding contact plug 245.

The shielding pattern SP connected to the upper bonding pad 222 may be connected to the peripheral circuit wirings PCL1 and PCL2 and/or the peripheral circuit PC, which are disposed in the peripheral circuit structure PS by the lower bonding pad 221. However, a connection relationship between the shielding pattern SP and the peripheral circuit structure PS is not limited thereto and may be changed in various ways.

According to an embodiment, a length of the bit lines BL and a length of the shielding pattern SP in the second direction Y may be different from each other. Accordingly, the bit lines BL may include a portion not overlapping the shielding pattern SP in the third direction Z which is the vertical direction.

The bit line contact plug 247 may be connected around the end of the bit lines BL that does not overlap the shielding pattern SP in the third direction Z. For example, the bit line contact plug 247 may be connected to the second metal layer 165 of the bit lines BL that does not overlap the shielding pattern SP in the third direction Z.

A bit line BL may be electrically connected to the upper bonding pad 222 through the bit line contact plug 247 penetrating through the upper bonding insulation layer 216, the first lower insulation layer 177, the spacer insulation layer 175, the bit line etch stop layer 171, and the bit line hard mask layer 167. For example, the bit line BL may be electrically connected to the upper bonding pad 222 through the lower wiring 232 and the lower contact plug 231 connected to the bit line contact plug 247.

The bit line BL connected to the upper bonding pad 222 may be connected to the peripheral circuit wirings PCL1 and PCL2 and/or the peripheral circuit PC, which are disposed in the peripheral circuit structure PS, by the lower bonding pad 221. However, a connection relationship between the bit line BL and the peripheral circuit structure PS is not limited thereto and may be changed in various ways.

A first active pattern AP1 and a second active pattern AP2 may be disposed on the bit line BL. The first active pattern AP1 and the second active pattern AP2 may be alternately disposed in the second direction Y.

The first active patterns AP1s may be spaced apart by a regular spacing from each other in the first direction X. The second active patterns AP2s may be spaced apart by a regular spacing from each other in the first direction X. The first and second active patterns AP1s and AP2s may be two-dimensionally arranged on a plane in the first direction X and the second direction Y that intersect each other. For example, each of the first active pattern AP1s and each of the second active pattern AP2s may be disposed to face each other and to be spaced apart from each other in the second direction Y.

Each of the first active pattern AP1 and the second active pattern AP2 may be made of a single crystal semiconductor material. For example, each of the first active pattern AP1 and the second active pattern AP2 may be made of single crystal silicon.

Each of the first active pattern AP1 and the second active pattern AP2 may have a length in the first direction X, a width in the second direction Y, and a height in the third direction Z. Each of the first active pattern AP1 and the second active pattern AP2 may have a substantially uniform width. For example, each of the first active pattern AP1 and the second active pattern AP2 may have the same or substantially the same width on first and second surfaces opposing each other in the third direction Z which is the vertical direction.

In addition, the width of first active pattern AP1 may be the same as the width of second active pattern AP2. However, the inventive concept is not limited thereto, and in some embodiments, the first active pattern AP1 and the second active pattern AP2 may respectively have widths different from each other on the first and second surfaces opposing each other in the third direction Z which is the vertical direction. For example, each width of the first active pattern AP1 and the second active pattern AP2 may become wider as the pattern is farther away from the bit line BL. Accordingly, the respective widths of the first and second active patterns AP1 and AP2 on the first and second surfaces may be different from each other.

As shown in FIGS. 2 and 3, the first surfaces of the first and second active patterns AP1 and AP2 may be in contact with the polysilicon layer 161 of the bit line BL. Alternatively, unlike shown in FIGS. 2 and 3, in some embodiments, the first surfaces of the first and second active patterns AP1 and AP2 may be in contact with the first metal layer 163 when the polysilicon layer 161 is omitted.

The length of each of the first and second active patterns AP1 and AP2 may be greater than a line width of the bit line BL. For example, the length of each of the first and second active patterns AP1 and AP2 may be greater than the width of the bit line BL in the first direction.

Although not shown in the drawings, in some embodiments, each of the first and second active patterns AP1 and AP2 may include a first dopant region adjacent to the bit line BL, a second dopant region adjacent to the buried contact BC, and a channel region between the first and second dopant regions. The first and second dopant regions may be regions doped with dopant in the first and second active patterns AP1 and AP2, and dopant concentration in the first and second active patterns AP1 and AP2 may be greater than dopant concentration in the channel region. However, the inventive concept is not limited thereto, and in some embodiments, each of the first active pattern AP1 and the second active pattern AP2 may not include at least one of the first dopant region and the second dopant region.

The first and second active patterns AP1 and AP2 may be controlled by the first and second word lines WL1 and WL2 as described below and the back gate electrodes BG as described below during an operation of the semiconductor device. Each of the first and second active patterns AP1 and AP2 may be made of the single crystal semiconductor material, thus improving a leakage current feature of the semiconductor memory device.

The back gate electrode BG may be disposed on the bit line BL and the shielding pattern SP. The back gate electrode BG may be disposed between the first active pattern AP1 and the second active pattern AP2, which are adjacent to each other in the second direction Y, and may extend across the bit line BL in the first direction X. For example, the first active pattern AP1 may be disposed on one side of each back gate electrode BG, and the second active pattern AP2 may be disposed on the other side of each back gate electrode BG. A height of the back gate electrode BG in the third direction Z may be smaller than each height of the first and second active patterns AP1 and AP2 in the third direction Z.

The first active pattern AP1 may be disposed between the first word line WL1 described below and the back gate electrode BG. The second active pattern AP2 may be disposed between the second word line WL2 and the back gate electrode BG described below. The pair of first word line WL1 and the second word line WL2 may be disposed between the back gate electrode BG adjacent thereto in the second direction Y.

The back gate electrode BG may be formed of and/or include a conductive material. For example, the back gate electrode BG may be formed of and/or include at least one of doped polysilicon, conductive metal nitride, conductive metal silicon nitride, metal carbonitride, conductive metal silicide, conductive metal oxide, the 2D material, and a metal.

The back gate electrode BG may be applied with a negative voltage during the operation of the semiconductor device and may increase a threshold voltage of the vertical channel transistor. For example, as the vertical channel transistor is miniaturized, the threshold voltage of the vertical channel transistor may be reduced, thus the negative voltage increasing the threshold voltage of the vertical channel transistor may lower leakage current.

The semiconductor device according to an embodiment may further include a first back gate isolation pattern 111, a second back gate isolation pattern 113, a back gate insulation pattern 115, and a back gate capping pattern 117.

The first back gate isolation pattern 111 and the second back gate isolation pattern 113 may be disposed between first and second active patterns AP1 and AP2 that are adjacent to each other in the second direction Y. The first back gate isolation pattern 111 and the second back gate isolation pattern 113 may extend in the first direction X to be parallel to the back gate electrode BG. The first back gate isolation pattern 111 may be in contact with the first and second active patterns AP1 and AP2. The second back gate isolation pattern 113 may be disposed to be spaced apart from the first and second active patterns AP1 and AP2 while having the first back gate isolation pattern 111 therebetween.

The back gate electrode BG may include a first surface and a second surface opposing each other in the third direction Z which is the vertical direction. The first surface of the back gate electrode BG may face the bit line BL and the shielding pattern SP, and the second surface of the back gate electrode BG may face the first back gate isolation pattern 111 and the second back gate isolation pattern 113. For example, the first back gate isolation pattern 111 and the second back gate isolation pattern 113 may be disposed on the second surface of the back gate electrode BG.

Each of the first back gate isolation pattern 111 and the second back gate isolation pattern 113 may be formed of and/or include an insulation material. Each of the first back gate isolation pattern 111 and the second back gate isolation pattern 113 may include at least one of a silicon oxide film, a silicon oxynitride film, or a silicon nitride film. For example, the first back gate isolation pattern 111 may include a silicon oxide film, and the second back gate isolation pattern 113 may include at least one of a silicon oxynitride film and a silicon nitride film. However, the materials included in the first back gate isolation pattern 111 and the second back gate isolation pattern 113 are not limited thereto and may be changed in various ways.

The first back gate isolation pattern 111 and the second back gate isolation pattern 113, or an upper surface thereof, may be disposed at the same or substantially the same level as a second gate capping pattern 155 described below. The second back gate isolation pattern 113 may be formed of and/or include the same material as the second gate capping pattern 155.

As used herein, the same level refers to being in the same horizontal plane in the context of the drawings in which the Z direction is normal to the horizontal plane. Objects at the same level have at least a portion that is in the same XY plane, in the context of the drawings. When referring to surfaces, the same level indicates that the surfaces being referred to are aligned to the same horizontal plane.

The back gate insulation pattern 115 may be disposed between the back gate electrode BG and the first active pattern AP1 or between the back gate electrode BG and the second active pattern AP2. In addition, the back gate insulation pattern 115 may be disposed between the back gate electrode BG and a gate insulation pattern GOX described below.

The back gate insulation pattern 115 may include a vertical part covering each of two side surfaces of the back gate electrode BG and a horizontal part connecting the vertical parts to each other. For example, the vertical part of the back gate insulation pattern 115 may cover each of the two side surfaces of the back gate electrode BG, and the horizontal part of the back gate insulation pattern 115 may cover the second surface of back gate electrode BG. For example, the back gate insulation pattern 115 and the second back gate isolation pattern 113 may be disposed sequentially on the second surface of back gate electrode BG.

The back gate insulation pattern 115 may include, for example, a silicon oxide film, a silicon oxynitride film, a high-k insulation film with a higher dielectric constant than a silicon oxide film, or a combination thereof.

The back gate capping pattern 117 may be disposed between the bit line BL and the back gate electrode BG, and cover the back gate electrode BG. For example, the back gate capping pattern 117 may cover the first surface of the back gate electrode BG.

The back gate capping pattern 117 may include a first surface facing the bit line BL and the shielding pattern SP in the third direction Z which is the vertical direction and a second surface facing the back gate electrode BG. The first surface of the back gate capping pattern 117 may be in contact with the bit line BL and the shielding pattern SP and the second surface may be in contact with the first surface of the back gate electrode BG. The two side surfaces of the back gate capping pattern 117 may be covered by the back gate insulation pattern 115.

The back gate capping pattern 117 may be formed of and/or include an insulation material. For example, the back gate capping pattern 117 may be formed of and/or include any one of silicon oxide, silicon nitride, silicon nitric oxide, or a combination thereof. However, a material included in the back gate capping pattern 117 is not limited thereto and may be changed in various ways.

Each of the first word line WL1 and the second word line WL2 may be disposed on the bit line BL and the shielding pattern SP. Each of the first word line WL1 and the second word line WL2 may overlap the bit line BL and the shielding pattern SP in the third direction Z and may extend in the first direction X. The first word line WL1 and the second word line WL2 may be spaced apart from each other in the second direction Y and may be alternately disposed in the second direction Y. The first active pattern AP1 and the second active pattern AP2 may be disposed between a first word line WL1 and a second word line WL2 that are adjacent to one another in the second direction Y.

Each of the first and second word lines WL1 and WL2 may include a first surface and a second surface opposing the first surface in the third direction Z which is the vertical direction. The first surface of each of the first and second word lines WL1 and WL2 may face the bit line BL and the shielding pattern SP, and the second surface thereof may face the buried contact BC described below and the second gate capping pattern 155 described below.

The first word line WL1 and the second word line WL2 may be disposed between the bit line BL and the buried contact BC which is described below and may extend in the third direction Z. Unlike the embodiment shown in FIGS. 2 and 3, in some embodiments, each of the first and second word lines WL1 and WL2 may have an L-shaped cross-section.

In an embodiment, each length of the first and second word lines WL1 and WL2 in the third direction Z may be the same or substantially the same as a length of the back gate electrode BG in the third direction Z. For example, each of the first and second surfaces of the first and second word lines WL1 and WL2 may be disposed at the same or the same or substantially the same level as each of the first and second surfaces of the back gate electrode BG and may overlap the same in the second direction Y. However, a relationship between each length of the first and second word lines WL1 and WL2 in the third direction Z and the length of the back gate electrode BG in the third direction Z and an arrangement relationship between the first and second word lines WL1 and WL2 and the back gate electrode BG are not limited thereto and may be changed in various ways.

In addition, in some embodiments, each length of the first and second word lines WL1 and WL2 in the third direction Z may be smaller than each length of the first and second active patterns AP1 and AP2 in the third direction Z.

Each of the first and second word lines WL1 and WL2 may be formed of and/or include a conductive material, and include, for example, at least one of doped polysilicon, conductive metal nitride, conductive metal silicon nitride, metal carbonitride, conductive metal silicide, conductive metal oxide, a 2D material, and a metal.

The semiconductor device according to an embodiment may further include a word line contact plug 241 connecting the word lines WL1 and WL2 and the peripheral circuit structure PS to each other.

According to an embodiment, as extension directions of the bit line BL and the word lines WL1 and WL2 are different from each other, each of the word lines WL1 and WL2 may include a portion that does not overlap the bit line BL in the third direction Z which is the vertical direction. For example, the word line contact plug 241 may be connected around an end of the second word line WL2 that does not overlap the bit line BL in the third direction Z.

The second word line WL2 may be electrically connected to the upper bonding pad 222 through the word line contact plug 241 that penetrates through the upper bonding insulation layer 216, the first lower insulation layer 177, the spacer insulation layer 175, the second lower insulation layer 173, the bit line etch stop layer 171, and a first gate capping pattern 153 described below. For example, the second word line WL2 may be electrically connected to the upper bonding pad 222 through the lower wiring 232 and the lower contact plug 231 connected to the word line contact plug 241.

The second word line WL2 connected to the upper bonding pad 222 may be connected to the peripheral circuit wirings PCL1 and PCL2 and/or the peripheral circuit PC which are disposed in the peripheral circuit structure PS by the lower bonding pad 221. However, a connection relationship between the second word line WL2 and the peripheral circuit structure PS is not limited thereto and may be changed in various ways.

Although the second word line WL2 is used as an example, a connection relationship between the second word line WL2 and another component may be applied the same as or substantially the same as a connection relationship between the first word line WL1 and another component.

The semiconductor device according to an embodiment may further include the gate insulation pattern GOX disposed on the side surface of each of the word lines WL1 and WL2, a gate separation pattern 151 disposed between the word lines WL1 and WL2, the first gate capping pattern 153 disposed on each of the first and second surfaces of the word lines WL1 and WL2, and the second gate capping pattern 155.

The gate insulation pattern GOX may extend in the third direction Z between the active patterns AP1 and AP2 and the word lines WL1 and WL2 to be disposed between the active patterns AP1 and AP2 and the first and second gate capping patterns 153 and 155.

In addition, a portion of the gate insulation pattern GOX may be disposed on a side surface of the cell region element isolation layer STI. For example, a portion of the gate insulation pattern GOX may be disposed between the cell region element isolation layer STI and the first gate capping pattern 153 described below. Accordingly, the gate insulation pattern GOX disposed on the cell region element isolation layer STI may be a remaining part in a process of patterning the gate insulation pattern GOX.

The gate insulation pattern GOX may be made of a silicon oxide film, a silicon oxynitride film, a high-k film with a higher dielectric constant than the silicon oxide film, or a combination thereof. The high-k film may be made of metal oxide or metal oxynitride. For example, the high-k film which may be used as the gate insulation pattern GOX may be made of hafnium oxide (HfO₂), hafnium silicon oxide (HfSiO), hafnium silicon oxynitride (HfSiON), hafnium tantalite (HfTaO), hafnium titanate (HfTiO), hafnium zirconium oxide (HfZrO), zirconium dioxide (ZrO₂), alumina (Al₂O₃), or a combination thereof, and is not limited thereto.

The gate separation pattern 151 may be disposed between the first and second word lines WL1 and WL2. The gate separation pattern 151 may be disposed between the first and second gate capping patterns 153 and 155 described below. The gate separation pattern 151 may be in contact with the first and second word lines WL1 and WL2. The first and second word lines WL1 and WL2 may be separated from each other by the gate separation pattern 151. The gate separation pattern 151 may extend in the third direction Z between the first and second word lines WL1 and WL2.

In detail, the gate separation pattern 151 may include a first surface and a second surface opposing each other in the third direction Z which is the vertical direction. The first surface of the gate separation pattern 151 may face the first gate capping pattern 153 and the second surface thereof may face the second gate capping pattern 155 described below. The center of the first surface of the gate separation pattern 151 may be recessed toward the second surface, and the second surface may include a curved surface.

The recess of the center of the first surface of the gate separation pattern 151 may be a result of a process step of depositing the gate separation pattern 151, during which a discontinuous boundary surface, for example, a seam, may be formed in the gate separation pattern 151 due to a step coverage property. Accordingly, in a process step of etching the gate separation pattern 151, a portion where the seam is formed may be partially recessed, and the center of the first surface of the gate separation pattern 151 may be recessed.

The first gate capping pattern 153 may be disposed between the spacer insulation layer 175 and the first and second word lines WL1 and WL2, and between the spacer insulation layer 175 and the gate separation pattern 151.

In detail, the first gate capping pattern 153 may be disposed on the first surface of each of the first and second word lines WL1 and WL2 and the first surface of the gate separation pattern 151. The first gate capping pattern 153 may surround the first surface of the gate separation pattern 151 and a portion of each of the two side surfaces of the gate separation pattern 151.

As shown in FIG. 2, the first gate capping pattern 153 may cover the first surface of the second word line WL2 and the end of the second word line WL2. The first gate capping pattern 153 covering the end of the second word line WL2 may face the cell region element isolation layer STI while having the gate insulation pattern GOX therebetween. Although the first word line WL1 is not shown in the drawing, an arrangement relationship between the second word line WL2 and the first gate capping pattern 153 may be applied the same or substantially the same as an arrangement relationship between the first word line WL1 and the first gate capping pattern 153.

The second gate capping pattern 155 may be disposed between the first and second word lines WL1 and WL2 and a contact interlayer insulation layer 271 described below.

In detail, the second gate capping pattern 155 may be disposed on the second surface of each of the first and second word lines WL1 and WL2 and the second surface of the gate separation pattern 151.

The second gate capping pattern 155 may surround the second surface of the gate separation pattern 151 and a portion of each of the two side surfaces of the gate separation pattern 151. For example, the second gate capping pattern 155 may extend in the second direction Y, which is the horizontal direction, on the second surface of the gate separation pattern 151, and extend in the third direction Z, which is the vertical direction, on the two side surfaces of the gate separation pattern 151.

The gate separation pattern 151, the first gate capping pattern 153, and the second gate capping pattern 155 may be formed of and/or include silicon oxide, silicon nitride, or a combination thereof. The above pattern may be formed of and/or include an insulation material. For example, the gate separation pattern 151 may include be formed of and/or silicon oxide, and each of the first and second gate capping patterns 153 and 155 may be formed of and/or include silicon nitride.

The semiconductor device according to an embodiment may further include the contact interlayer insulation layer 271, a pad separation insulation layer 273, and a contact etch stop layer 275.

The contact interlayer insulation layer 271, the pad separation insulation layer 273, and the contact etch stop layer 275 may be formed of and/or include silicon oxide, silicon nitride, or a combination thereof. The above layer may be formed of and/or include an insulation material.

The contact interlayer insulation layer 271 may be disposed on the active patterns AP1 and AP2. The contact interlayer insulation layer 271 may cover the first and second back gate isolation patterns 111 and 113, the second gate capping pattern 155, and the cell region element isolation layer STI.

The buried contact BC, the cell landing pad LP, and the cell capacitor DSP may be sequentially stacked in the cell array structure CS disposed in the cell array region CAR.

The buried contact BC may penetrate through the contact interlayer insulation layer 271. The buried contact BC may be connected to each of the first and second active patterns AP1 and AP2. The buried contacts BC adjacent to each other may be separated from each other by the contact interlayer insulation layer 271.

Each buried contact BC may have a variety of planar shapes such as circular, oval, rectangular, square, diamond, and hexagonal shapes.

The buried contact BC may be formed of and/or include a conductive material. The buried contact BC may be formed of and/or include, for example, at least one of doped polysilicon, conductive metal nitride, conductive metal silicon nitride, metal carbonitride, conductive metal silicide, conductive metal oxide, a 2D material, and a metal.

The cell landing pad LP may be disposed on the buried contact BC. The landing pad LP may have various shapes on a plane such as a circular, oval, rectangular, square, diamond, and hexagonal shapes.

The pad separation insulation layer 273 may be disposed on the contact interlayer insulation layer 271. The pad separation insulation layer 273 may be disposed between the cell landing pads LP. The cell landing pads LP may be arranged on a plane in a matrix pattern in the first direction X and the second direction Y. An upper surface of the cell landing pad LP may be substantially coplanar with an upper surface of the pad separation insulation layer 273.

The cell landing pad LP may be formed of and/or include a conductive material. The conductive material may include, for example, at least one of doped polysilicon, conductive metal nitride, conductive metal silicon nitride, metal carbonitride, conductive metal silicide, conductive metal oxide, a 2D material, and a metal.

Each cell capacitor DSP may be disposed on each cell landing pad LP. The cell capacitor DSP may be connected to each of the first and second active patterns AP1 and AP2.

As shown in FIG. 1, the cell capacitor DSP may be arranged in the matrix pattern in the first direction X and the second direction Y. The cell capacitor DSP may completely or partially overlap the cell landing pad LP in the third direction Z. The cell capacitor DSP may be in contact with the entire or partial upper surface of the cell landing pad LP.

Each cell capacitor DSP may include a cell lower electrode 251, a cell upper electrode 255, and a cell dielectric film 253 interposed between the cell lower electrode 251 and the cell upper electrode 255.

The cell lower electrode 251 may have a variety of planar shapes such as a circular, oval, rectangular, square, diamond, and hexagonal shapes. The cell lower electrode 251 may penetrate through the contact etch stop layer 275 to be in contact with the cell landing pad LP. The cell lower electrode 251 may be disposed on the cell landing pad LP and extend in the third direction Z which is the vertical direction.

Although not shown in the drawing, the cell capacitor DSP may further include a supporter pattern disposed between the cell lower electrodes 251. The supporter pattern disposed between the cell lower electrodes 251 may prevent collapse of the cell lower electrode 251 extending in the third direction Z, which is the vertical direction.

The cell lower electrode 251 may be formed of and/or include a metal, conductive metal nitride, or a combination thereof. For example, the cell lower electrode 251 may be made of titanium nitride (TiN), ruthenium (Ru), tantalum nitride (TaN), tungsten nitride (WN), platinum (Pt), Iridium (Ir), or a combination thereof. However, a material included in the cell lower electrode 251 is not limited thereto and may be changed in various ways.

The cell dielectric film 253 may be disposed conformally along profiles of the upper and side surfaces of the cell lower electrode 251. For example, the cell dielectric film 253 may cover the side and upper surfaces of the cell lower electrode 251. A portion of the cell dielectric film 253 may be disposed on the upper surface of the contact etch stop layer 275. For example, a portion of the cell dielectric film 253 may be disposed between the contact etch stop layer 275 and the cell upper electrode 255.

The cell dielectric film 253 may be formed of and/or include tantalum oxide (Ta₂O₅), aluminum oxide (Al₂O₃), titanium oxide (TiO₂), or a combination thereof. However, the inventive concept is not limited thereto, and a material included in the cell dielectric film 253 may be changed in various ways.

The cell upper electrode 255 may be disposed on the cell dielectric film 253. The cell upper electrode 255 may entirely cover the cell lower electrode 251. For example, the cell upper electrode 255 may cover the upper and side surfaces of the cell lower electrode 251.

The cell upper electrode 255 may include a protrusion extending along the side surface of cell lower electrode 251 in the first direction X which is the horizontal direction and disposed on the contact etch stop layer 275. For example, the protrusion of the cell upper electrode 255 may correspond to an end of the cell upper electrode 255 and the end of the cell upper electrode 255 May be disposed on the contact etch stop layer 275.

In detail, the cell upper electrode 255 may include a first part 255a covering the upper surface of the cell lower electrode 251 and extending in the first direction X which is the horizontal direction, a second part 255b covering the side surface of the cell lower electrode 251 and extending in the third direction Z, and a third part 255c extending from a side surface of the second part 255b of the cell lower electrode 251 in the first direction X which is the horizontal direction, and disposed on the contact etch stop layer 275.

In some embodiments, the third part 255c of the cell upper electrode 255 may be omitted. For example, in a step of forming the cell upper electrode 255, the third part 255c of the cell upper electrode 255 may be omitted based on a method of patterning a material layer for forming the cell upper electrode 255.

The third part 255c of the cell upper electrode 255 may extend in the horizontal direction from the second part 255b of the cell upper electrode 255 in contact with the contact etch stop layer 275. For example, the third part 255c of the cell upper electrode 255 may be a part protruding in the first direction X, which is the horizontal direction, from the second part 255b of the cell upper electrode 255. The third part 255c of the cell upper electrode 255 may be in contact with the cell dielectric film 253 disposed on the contact etch stop layer 275. In addition, an end of the third part 255c of the cell upper electrode 255 may be aligned at the same or substantially the same boundary as an end of the cell dielectric film 253.

The third part 255c of the cell upper electrode 255 may be disposed across the cell array region CAR and the peripheral circuit region PAR. For example, the third part 255c of the cell upper electrode 255 may have a portion disposed in the cell array region CAR and the other portion disposed in the peripheral circuit region PAR. However, a region where the third part 255c of the cell upper electrode 255 is disposed is not limited thereto and may be changed in various ways. For example, the end of the third part 255c of the cell upper electrode 255 may be disposed in the cell array region CAR.

In an embodiment, the cell upper electrode 255 may be electrically connected to the upper bonding pad 222 through a capacitor contact plug 243 penetrating through the cell dielectric film 253, the upper bonding insulation layer 216, the contact etch stop layer 275, and the insulation layer disposed between the upper bonding insulation layer 216 and the contact etch stop layer 275. For example, the capacitor contact plug 243 may be connected to the third part 255c of the cell upper electrode 255.

For example, the cell upper electrode 255 may be electrically connected to the upper bonding pad 222 through the lower wiring 232 and the lower contact plug 231 which are connected to the capacitor contact plug 243.

The cell upper electrode 255 connected to the upper bonding pad 222 may be connected to the peripheral circuit wirings PCL1 and PCL2 and/or the peripheral circuit PC which are disposed in the peripheral circuit structure PS by the lower bonding pad 221. However, a connection relationship between the cell upper electrode 255 and the peripheral circuit structure PS is not limited thereto and may be changed in various ways.

The cell upper electrode 255 may be formed of and/or include a metal material such as tungsten (W), titanium (Ti), ruthenium (Ru), or silicon germanium (SiGe). For example, the cell upper electrode 255 may be formed of and/or include tungsten (W). However, a material included in the cell lower electrode 255 is not limited thereto and may be changed in various ways. For example, the cell upper electrode 255 may be formed of and/or include conductive metal nitride, metal silicide, or a combination thereof.

In an embodiment, the cell array structure CS disposed in the peripheral circuit region PAR may include one or more conductive pads MP. As shown in FIG. 1, one or more conductive pads MP may be arranged in a planar island shape. FIG. 1 shows that the plurality of conductive pads MP are arranged to be parallel to each other in the peripheral circuit region PAR in the first direction X and the second direction Y. However, an arrangement shape of the plurality of conductive pads MP on the plane is not limited thereto and may be changed in various ways.

Each of the plurality of conductive pads MP may have a variety of planar shapes such as the square, rectangular, circular, oval, diamond, and hexagonal shapes. In addition, a planar area of each of the plurality of conductive pads MP may be greater than a planar area of the cell capacitor DSP disposed in the cell array region CAR. However, the planar shape and size of the conductive pad MP are not limited thereto and may be changed in various ways.

The conductive pad MP may be formed of and/or include the same material as the cell capacitor DSP disposed in the cell array region CAR and the conductive pad MP, or a lower surface thereof, may be disposed at the same or substantially the same level as the end or lower surface of the cell capacitor DSP. For example, the conductive pad MP may be disposed at the same or substantially the same level as the protrusion of the cell capacitor DSP.

In detail, the conductive pad MP may be formed of and/or include the same material as the cell upper electrode 255 of the cell capacitor DSP disposed in the cell array region CAR. For example, the conductive pad MP may be formed of and/or include tungsten (W). However, a material included in the conductive pad MP is not limited thereto and may be changed in various ways.

The conductive pad MP, or an upper surface thereof, may be disposed at the same or substantially the same level as a portion of the cell upper electrode 255, or an upper surface thereof, of the cell capacitor DSP disposed in the cell array region CAR. For example, the conductive pad MP may be disposed at the same or substantially the same level as the third part 255c of the cell upper electrode 255 described above. In addition, a thickness of the conductive pad MP in the vertical direction may be the same or substantially the same as a thickness of the third part 255c of the cell upper electrode 255 in the vertical direction.

This configuration may be a result of simultaneously forming the conductive pad MP during a process step of forming the cell upper electrode 255 of the cell capacitor DSP. For example, in the step of forming a metal material layer to form the cell upper electrode in the cell array region CAR and the peripheral circuit region PAR, in order to form the cell upper electrode 255 in the cell array region CAR, the metal material may be patterned to form the cell upper electrode 255 in the cell array region CAR and form the conductive pad MP in the peripheral circuit region PAR.

The semiconductor device according to an embodiment may include a first upper insulation layer 277 and a second upper insulation layer 279 sequentially stacked on the contact etch stop layer 275. In addition, the semiconductor device according to an embodiment may include a first upper contact plug 261 and first upper wiring 262 which are disposed in the first upper insulation layer 277 and a second upper contact plug 263 and second upper wiring 264 which are disposed in the second upper insulation layer 279.

The first upper insulation layer 277 may cover the cell capacitor DSP and the conductive pad MP. For example, the first upper insulation layer 277 may cover the upper and side surfaces of the cell capacitor DSP and the upper and side surfaces of the conductive pad MP.

In the cell array region CAR, the cell capacitor DSP may be electrically connected to the first upper wiring 262 through the first upper contact plug 261 and the first upper wiring 262 may be electrically connected to the second upper wiring 264 through the second upper contact plug 263.

In an embodiment, the first upper wiring 262 may be rewiring (or a redistribution layer (RDL)) connected to wiring to which an external voltage is applied, or a contact plug connected to wiring to which a voltage is applied. At least a portion of the second upper wiring 264 may correspond to power wiring to which the external voltage is applied. However, this configuration is an example, and functions of the first upper wiring 262 and the second upper wiring 264 may be changed in various ways.

The first upper contact plug 261, the first upper wiring 262, the second upper contact plug 263, and the second upper wiring 264 may be formed of and/or include at least one metal such as copper (Cu), aluminum (Al), tungsten (W), titanium (Ti), and tantalum (Ta), or a combination thereof. For example, the first upper contact plug 261, the second upper contact plug 263, and the second upper wiring 264 may be formed of and/or include at least one of aluminum (Al), tungsten (W), titanium (Ti), and tantalum (Ta), and the first upper wiring 262 may be formed of and/or include copper (Cu).

In the peripheral circuit region PAR, the conductive pad MP may be sequentially electrically connected to the first upper wiring 262, the second upper contact plug 263, and the second upper wiring 264 through the upper conductive contact plug MC_T, and the conductive pad MP may be sequentially electrically connected to the lower wiring 232, the lower contact plug 231, the upper bonding pad 222, the lower bonding pad 221, and the peripheral circuit wirings PCL1 and PCL2 through the lower conductive contact plug MC_L.

Accordingly, the first and second upper wirings 262 and 264 disposed in an upper region of the cell array structure CS may be electrically connected to the peripheral circuit wirings PCL1 and PCL2 and/or the peripheral circuit PC which are disposed in the peripheral circuit structure PS through the upper conductive contact plug MC_T, the conductive pad MP, and the lower conductive contact plug MC_L.

In detail, the upper conductive contact plug MC_T may connect the conductive pad MP and the first upper wiring 262 to each other on the conductive pad MP. The conductive pad MP may be sequentially electrically connected to the first upper wiring 262, the second upper contact plug 263, and the second upper wiring 264 through the upper conductive contact plug MC_T.

FIG. 3 shows that the upper conductive contact plug MC_T is electrically connected to the second upper wiring 264 through the first upper wiring 262. However, their connection relationship is not limited thereto and may be changed in various ways. For example, the upper conductive contact plug MC_T may be directly connected to the second upper wiring 264.

The lower conductive contact plug MC_L may connect the conductive pad MP and the upper bonding pad 222 to each other under the conductive pad MP in the peripheral circuit region PAR. For example, the conductive pad MP may be electrically connected to the upper bonding pad 222 through the lower wiring 232 and the lower contact plug 231 which are connected to the lower conductive contact plug MC_L.

The conductive pad MP connected to the upper bonding pad 222 may be connected to the peripheral circuit wirings PCL1 and PCL2 and/or the peripheral circuit PC which are disposed in the peripheral circuit structure PS by the lower bonding pad 221.

For example, the conductive pad MP electrically connected to the upper bonding pad 222 through the lower conductive contact plug MC_L may be connected to the second peripheral circuit wiring PCL2 connected to the lower bonding pad 221 and the second peripheral circuit wiring PCL2 electrically connected to the conductive pad MP may be connected to the cell capacitor DSP through the capacitor contact plug 243 described above.

Accordingly, as described above, when the external voltage is applied to the second upper wiring 264, the voltage applied to the second upper wiring 264 may be applied to the cell upper electrode 255 of the cell capacitor DSP through first upper connection wiring 242, the upper conductive contact plug MC_T, the conductive pad MP, the lower conductive contact plug MC_L, the second peripheral circuit wiring PCL2 disposed in the circuit structure PS, and the cell capacitor contact plug 243.

For example, the conductive pad MP disposed in the peripheral circuit region PAR, which may be connected to the first and second upper wirings 262 and 264 to which the external voltage is applied through the upper conductive contact plug MC_T, may be electrically connected to the peripheral circuit structure PS through the lower conductive contact plug MC_L, and may thus serve as power transmission wiring connected to the power wiring to which the external voltage is applied. However, this configuration is an example. A connection relationship between the conductive pad MP and the upper conductive contact plug MC_T, a connection relationship between the conductive pad MP and the lower conductive contact plug MC_L, a connection relationship between the conductive pad MP and the peripheral circuit wirings PCL1 and PCL2 of the peripheral circuit structure PS, and a connection relationship between the conductive pad MP and the components disposed in the cell array region CAR are not limited thereto and may be changed in various ways.

In an embodiment, a width of the upper conductive contact plug MC_T in the first direction X may be reduced as the plug MC_T is closer to the substrate 200 based on its aspect ratio on a cross-section of the semiconductor device. A width of the lower conductive contact plug MC_L in the first direction X may be increased as the plug MC_L is farther away from the substrate 200 based on its aspect ratio on the cross-section.

In an embodiment, the lower conductive contact plug MC_L may have a first length h1 in the third direction Z which is the direction vertical to the substrate 200 and the upper conductive contact plug MC_T may have a second length h2 in the third direction Z which is the direction vertical to the substrate 200. For example, the first length h1 may be shorter than the second length h2. However, a relationship between the first length h1 and the second length h2 is not limited thereto and may be changed in various ways.

Each of the upper conductive contact plug MC_T and the lower conductive contact plug MC_L may be formed of and/or include a conductive material. For example, the conductive material may include at least one metal such as aluminum (Al), tungsten (W), titanium (Ti), tantalum (Ta), copper (Cu), or a combination thereof. However, the conductive material is not limited thereto and may be changed in various ways.

The semiconductor device according to an embodiment may have the conductive pad MP formed of and/or including the same material as the cell upper electrode 255 of the cell capacitor DSP disposed in the cell array region CAR. The conductive pad MP, which is disposed at the same level as the protrusion or end of the cell upper electrode 255, is formed in the peripheral circuit region PAR and the semiconductor device may use the conductive pad MP as connection wiring or a contact pad, thereby securing an improved electrical feature.

For example, the semiconductor device according to an embodiment may have a relatively improved electrical resistance feature and simultaneously have improved stability of an electrical connection between the wirings by connecting the wiring disposed in the upper region of the cell array structure CS and the wiring disposed in the peripheral circuit structure PS to each other through the conductive pad MP electrically connected to the conductive contact plug when compared to a case of directly electrically connecting the wiring disposed in the upper region of the cell array structure CS and the wiring disposed in the peripheral circuit structure PS to each other through the conductive contact plug.

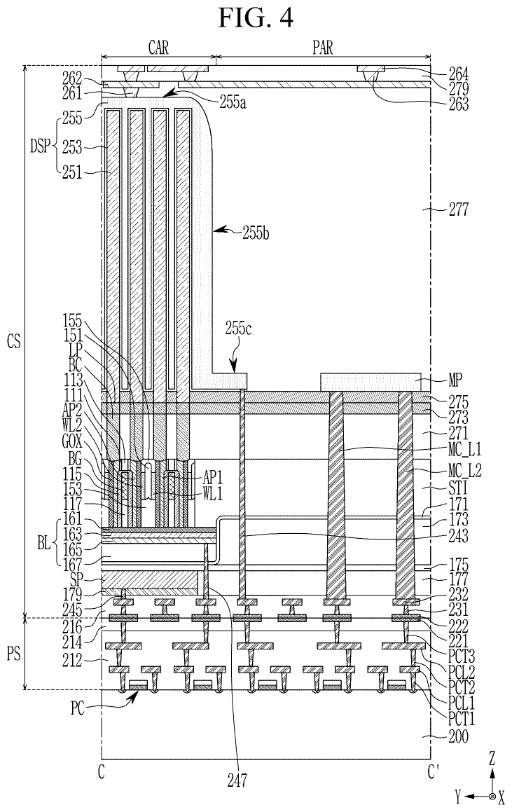

Hereinafter, the description describes a semiconductor device according to various embodiments with reference to FIGS. 4 to 16. In the following embodiments, the same reference numerals refer to the same or like components as in the embodiments previously described and redundant descriptions may be omitted or simplified and the differences are mainly described.

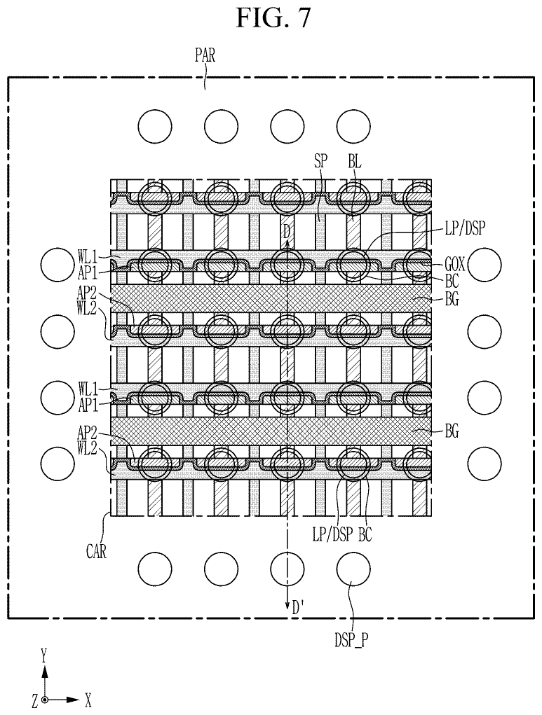

FIGS. 4 to 6, 8, 9, and 12 to 16 are views showing a cross-section of a semiconductor device according to some embodiments. FIGS. 7, 10, and 11 are plan views of the semiconductor device according to some embodiments.

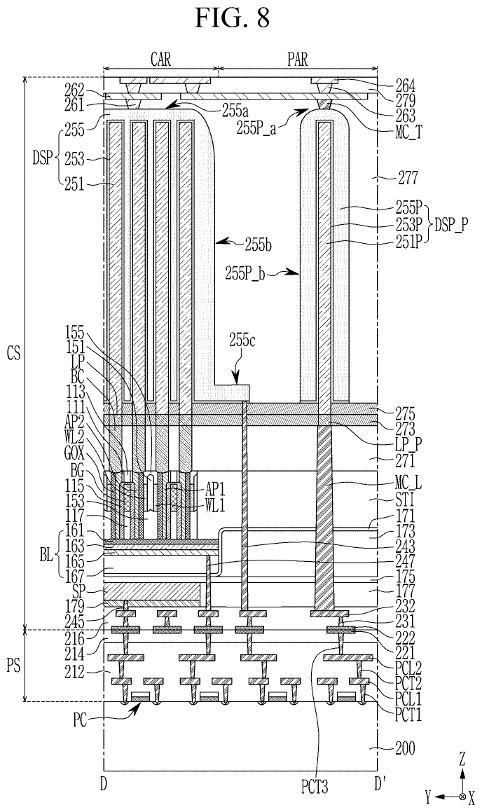

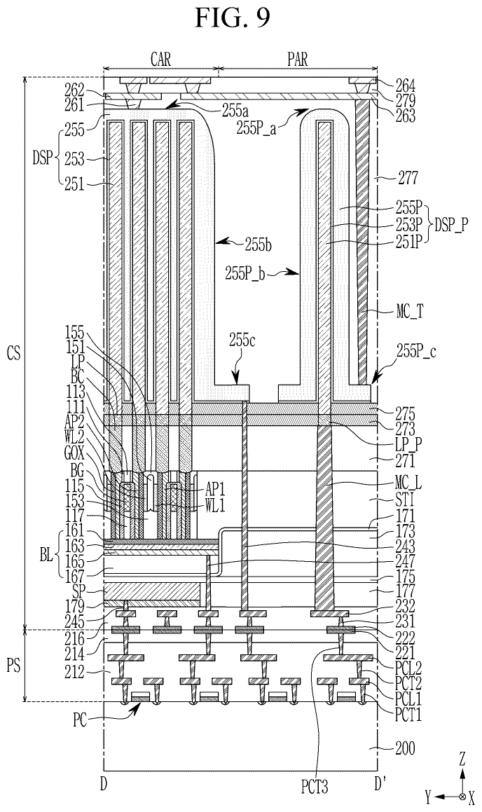

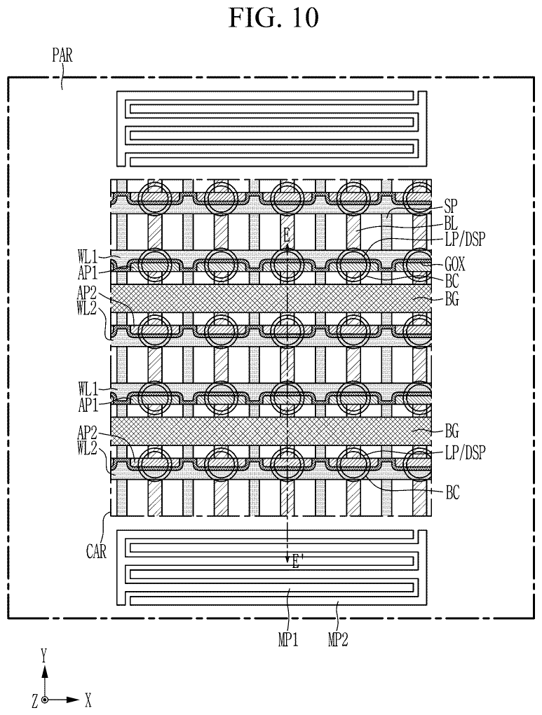

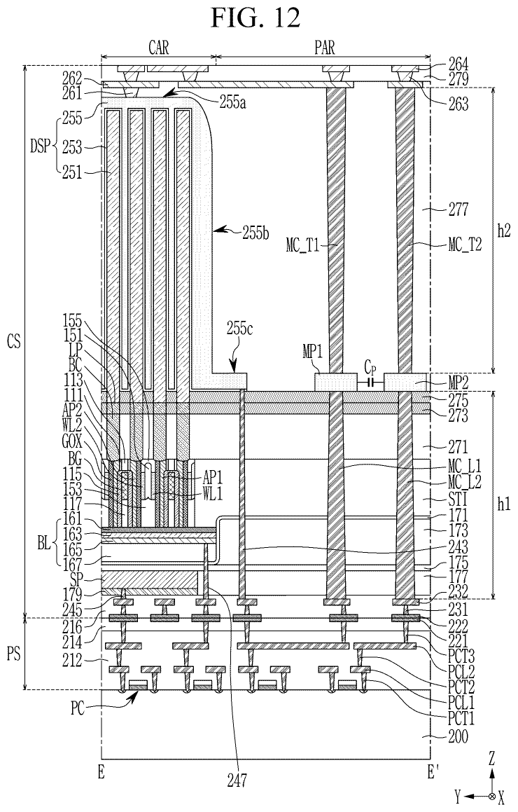

In detail, FIGS. 4 to 6 are views each showing the cross-section taken along the line C-C′ of FIG. 1 according to some embodiments. FIGS. 8 and 9 are views each showing the cross-section taken along line D-D′ of FIG. 7 according to some embodiments. FIGS. 12 to 16 are views each showing the cross-section taken along line E-E′ of FIG. 10 according to some embodiments.

An embodiment shown in FIG. 4 may be different from an embodiment shown in FIG. 3 in that the conductive pad MP disposed in the peripheral circuit region PAR has a different connection relationship.

In detail, referring to FIG. 4, unlike the conductive pad MP shown in FIG. 3, the conductive pad MP disposed in the peripheral circuit region PAR may be connected to the peripheral circuit structure PS through a plurality of lower conductive contact plugs MC_L1 and MC_L2 without connection to the first and second upper wirings 262 and 264. For example, unlike the conductive pad MP shown in FIG. 3, the conductive pad MP shown in this embodiment may be connected only to the peripheral circuit structure PS without connection to the upper wirings 262 and 264 disposed on an upper portion of the cell array structure CS.

The semiconductor device according to this embodiment may include the first lower conductive contact plug MC_L1 and the second lower conductive contact plug MC_L2 each connecting the conductive pad MP and the peripheral circuit structure PS to each other under the conductive pad MP in the peripheral circuit region PAR.

Each of the first lower conductive contact plug MC_L1 and the second lower conductive contact plug MC_L2 may connect the conductive pad MP and the upper bonding pad 222 to each other. The conductive pad MP connected to the first lower conductive contact plug MC_L1 may be electrically connected to the second peripheral circuit wiring PCL2 through the upper bonding pad 222, the lower bonding pad 221, and the third peripheral contact plug PCT3.

The conductive pad MP connected to the second lower conductive contact plug MC_L2 may be connected to the second peripheral circuit wiring PCL2, other than the second peripheral circuit wiring PCL2 electrically connected to the first lower conductive contact plug MC_L1, through the upper bonding pad 222, the lower bonding pad 221, and the third peripheral contact plug PCT3.

For example, the second peripheral circuit wiring PCL2 electrically connected to the conductive pad MP through the first lower conductive contact plug MC_L1 may be different wiring from the second peripheral circuit wiring PCL2 electrically connected to the conductive pad MP through the second lower conductive contact plug MC_L2. For example, the conductive pad MP may be electrically connected to the different second peripheral circuit wirings PCL2 respectively through the first lower conductive contact plug MC_L1 and the second lower conductive contact plug MC_L2. However, this configuration is an example, and a connection relationship between the conductive pad MP and the peripheral circuit wirings PCL1 and PCL2 and/or the peripheral circuit PC, which are included in the peripheral circuit structure PS, may be changed in various ways.

In this embodiment, the conductive pad MP may be signal transmission wiring or the power transmission wiring. For example, the conductive pad MP may be the signal transmission wiring for applying the same signal that is applied to the shielding pattern SP, the bit line BL, the word line WL, and the back gate electrode BG, disposed in the cell array region CAR by being electrically connected to the different peripheral circuit wirings PCL1 and PCL2 and/or peripheral circuits PC through the first lower conductive contact plug MC_L1 and the second lower conductive contact plug MC_L2.

As another example, the conductive pad MP may be the power transmission wiring for applying an externally applied voltage or a ground voltage. For example, the conductive pad MP may be a portion of the power transmission wiring connected to wiring for applying the voltage.

The semiconductor device according to an embodiment shown in FIG. 4 may include the conductive pad MP serving as the signal transmission wiring or the power transmission wiring in the peripheral circuit region PAR, thus achieving various design and improved integration while simultaneously securing the improved electrical feature.

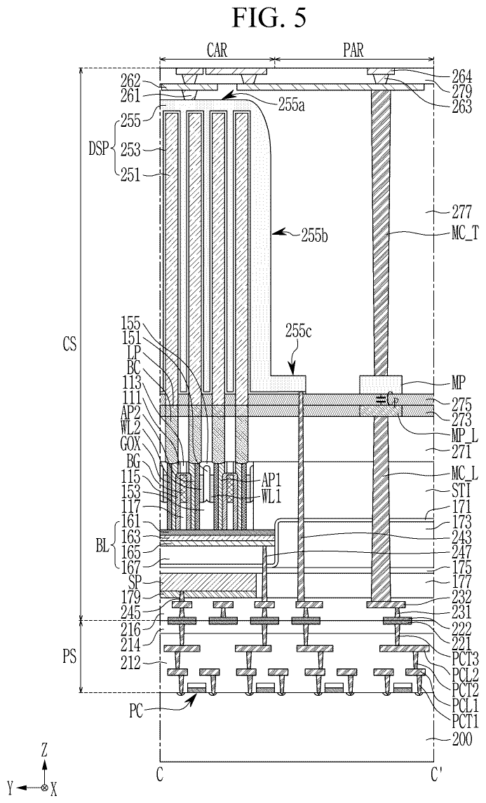

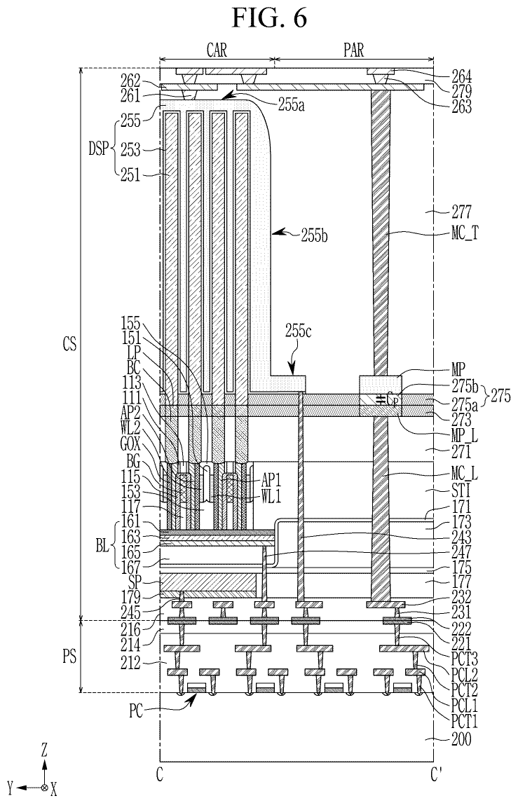

An embodiment shown in FIG. 5 or 6 may be different from an embodiment shown in FIG. 3 in that an additional conductive pad MP_L other than the conductive pad MP is further disposed in the peripheral circuit region PAR.

In detail, referring to FIG. 5, the additional conductive pad MP_L overlapping the conductive pad MP in the peripheral circuit region PAR in the third direction Z which is the vertical direction may be further disposed.

As described above, the conductive pad MP may be formed of and/or include the same material as the third part 255c of the cell upper electrode 255 of the cell capacitor DSP disposed in the cell array region CAR and may be disposed at the same or substantially the same level as the third part 255c of the cell upper electrode 255, or an upper surface of each may be disposed at the same or substantially the same level.

The additional conductive pad MP_L may be formed of and/or include the same material as the cell landing pad LP disposed in the cell array region CAR and may be disposed at the same or substantially the same level as the cell landing pad LP. For example, the additional conductive pad MP_L disposed in the peripheral circuit region PAR may be disposed in the pad separation insulation layer 273 like the cell landing pad LP disposed in the cell array region CAR.

This configuration may be a result of simultaneously forming the additional conductive pad MP_L in a process step of forming the cell landing pad LP disposed in the cell array region CAR. For example, in the step of forming a conductive material layer to form the cell upper electrode in the cell array region CAR and the peripheral circuit region PAR in order to form the cell landing pad LP in the cell array region CAR, the conductive material may be patterned to form the cell landing pad LP in the cell array region CAR, and form the additional conductive pad MP_L in the peripheral circuit region PAR.

The additional conductive pad MP_L may be formed of and/or include a conductive material. The conductive material may include, for example, at least one of doped polysilicon, conductive metal nitride, conductive metal silicon nitride, metal carbonitride, conductive metal silicide, conductive metal oxide, a 2D material, and a metal.

In the peripheral circuit region PAR, the additional conductive pad MP_L and the conductive pad MP may be disposed so that at least their portions overlap with each other in the third direction Z which is the vertical direction. For example, the additional conductive pad MP_L may be disposed under the conductive pad MP and these two pads may be spaced apart from each other while having the contact etch stop layer 275 therebetween. For example, an upper surface of the additional conductive pad MP_L and a lower surface of the conductive pad MP may face each other while having the contact etch stop layer 275 therebetween.

FIG. 5 shows that the widths of the additional conductive pad MP_L and the conductive pad MP in the first direction X are the same as each other. However, the inventive concept is not limited thereto, and a relationship between the widths of the additional conductive pad MP_L and the conductive pad MP may be changed in various ways. For example, the width of the additional conductive pad MP_L may be greater than the width of the conductive pad MP. As another example, the width of the conductive pad MP may be greater than the width of the additional conductive pad MP_L.

In addition, FIG. 5 shows that the additional conductive pad MP_L and the conductive pad MP completely overlap each other in the third direction Z which is the vertical direction. However, an overlap relationship between the additional conductive pad MP_L and the conductive pad MP is not limited thereto, and in some embodiments, the additional conductive pad MP_L and the conductive pad MP may partially overlap each other in the third direction Z which is the vertical direction.

The upper conductive contact plug MC_T may connect the conductive pad MP and the first upper wiring 262 to each other. Accordingly, the conductive pad MP may be electrically connected to the second upper wiring 264 through the second upper contact plug 263.

The lower conductive contact plug MC_L may connect the additional conductive pad MP_L and the upper bonding pad 222 to each other. For example, the additional conductive pad MP_L may be electrically connected to the upper bonding pad 222 through the lower wiring 232 and the lower contact plug 231 which are connected to the lower conductive contact plug MC_L.

The additional conductive pad MP_L connected to the upper bonding pad 222 may be connected to the peripheral circuit wirings PCL1 and PCL2 and/or the peripheral circuit PC which are disposed in the peripheral circuit structure PS by the lower bonding pad 221. However, a connection relationship between the additional conductive pad MP_L and the peripheral circuit structure PS is not limited to thereto in embodiments of the inventive concept and may be changed in various ways.

In this embodiment, a peripheral sub-capacitor C_{P} may be formed by including the additional conductive pad MP_L and the conductive pad MP facing each other in the third direction Z which is the vertical direction and the contact etch stop layer 275 disposed between the additional conductive pad MP_L and the conductive pad MP. For example, the conductive pad MP to which a first voltage is applied through the upper conductive contact plug MC_T may function as a first electrode, the additional conductive pad MP_L to which a second voltage different from the first voltage is applied through the lower conductive contact plug MC_L may function as a second electrode, and a portion of the contact etch stop layer 275 disposed between the conductive pad MP and the additional conductive pad MP_L may function as a dielectric. For example, the peripheral sub-capacitor C_{P} may be a metal-insulator-metal (MIM) capacitor including the additional conductive pad MP_L, the conductive pad MP and a portion of the contact etch stop layer 275.

FIGS. 5 and 6 show that one peripheral sub-capacitor C_{P} is disposed in the peripheral circuit region PAR. However, the number and arrangement of the peripheral sub-capacitor C_{P} disposed in the peripheral circuit region PAR are not limited thereto and may be changed in various ways. Its details are described below.

An embodiment shown in FIG. 6 may be different from an embodiment shown in FIG. 5 in that the contact etch stop layer 275 includes a first contact etch stop layer 275a and a second contact etch stop layer 275b disposed between the conductive pad MP and the additional conductive pad MP_L in the peripheral circuit region PAR.

In detail, referring to FIG. 6, in the cell array region CAR and the peripheral circuit region PAR, the first contact etch stop layer 275a may be disposed in a region where the conductive pad MP and the additional conductive pad MP_L do not overlap each other in the third direction Z which is the vertical direction, and the second contact etch stop layer 275b may be disposed in a region where the conductive pad MP and the additional conductive pad MP_L overlap each other in the third direction Z, which is the vertical direction.

The first contact etch stop layer 275a and the second contact etch stop layer 275b may be disposed at the same or substantially the same level. The second contact etch stop layer 275b may be surrounded by the first contact etch stop layer 275a.

In the peripheral circuit region PAR, the second contact etch stop layer 275b may be disposed between the conductive pad MP and the additional conductive pad MP_L. For example, the first contact etch stop layer 275a may not overlap the conductive pad MP or the additional conductive pad MP_L, and the second contact etch stop layer 275b may overlap the conductive pad MP and the additional conductive pad MP_L in the third direction Z, which is vertical to the conductive pad MP.

FIG. 6 shows that two side surfaces of the second contact etch stop layer 275b disposed between the conductive pad MP and the additional conductive pad MP_L are aligned on the same boundary as two side surfaces of the conductive pad MP and two side surfaces of the additional conductive pad MP_L. However, an arrangement relationship of the conductive pad MP, the additional conductive pad MP_L and the second contact etch stop layer 275b is not limited thereto and may be changed in various ways.

For example, the two side surfaces of the second contact etch stop layer 275b may be aligned on a different boundary from the two side surfaces of the conductive pad MP and/or the two side surfaces of the additional conductive pad MP_L. For example, a width of the second contact etch stop layer 275b in the first direction X may be different from a width of the conductive pad MP and/or a width of the additional conductive pad MP_L in the first direction X.

The first contact etch stop layer 275a and the second contact etch stop layer 275b may be formed by separate process steps. For example, the first contact etch stop layer 275a may be formed and then an opening may then be formed by removing a portion of the first contact etch stop layer 275a that corresponds to the additional conductive pad MP_L, and the second contact etch stop layer 275b may then be formed in the opening.

In an embodiment, the first contact etch stop layer 275a and the second contact etch stop layer 275b may be formed of and/or include materials different from each other. The second contact etch stop layer 275b may be formed of and/or include a material with a relatively high-k compared to the first contact etch stop layer 275a. For example, a high-k material may be formed of and/or include oxide including one or more of titanium (Ti), tantalum (Ta), niobium (Nb), lanthanum (La), barium (Ba), strontium (Sr), yttrium (Y), and lutetium (Lu). However, the high-k material is not limited to thereto in embodiments of the inventive concept and may be changed in various ways.

Accordingly, the second contact etch stop layer 275b may have a dielectric constant higher than that of the contact etch stop layer 275.

In this embodiment, the peripheral sub-capacitor C_{P} may be formed by including the additional conductive pad MP_L and the conductive pad MP facing each other in the third direction Z, which is the vertical direction, and the second contact etch stop layer 275b disposed between the additional conductive pad MP_L and the conductive pad MP. As described above, the second contact etch stop layer 275b disposed between the conductive pad MP and the additional conductive pad MP_L may function as the dielectric. For example, compared to an embodiment shown in FIG. 5, the second contact etch stop layer 275b with the relatively high-k may be formed between the conductive pad MP and the additional conductive pad MP_L to thus increase capacitance of the peripheral sub-capacitor C_{P}.

According to an embodiments shown in FIG. 5 or 6, the peripheral sub-capacitor C_{P} disposed in the peripheral circuit region PAR may be connected to the first and second upper wirings 262 and 264, the peripheral wirings PCL1 and PCL2, and the peripheral circuit PC, which are disposed in the peripheral circuit structure PAR, or the like to thus prevent a rapid change in each of various voltages applied to the respective components, thereby ensuring stable supply of the voltage. For example, the peripheral sub-capacitor C_{P} may remove a noise from the voltage applied to each component.

An embodiment shown in any of FIGS. 7 to 9 is different from an embodiment shown in FIG. 1 or 3 in that a peripheral capacitor DSP_P, which has the same or substantially the same structure as the cell capacitor DSP disposed in the cell array region CAR, is disposed in the peripheral circuit region PAR.

In detail, referring to FIGS. 7 and 8, a peripheral landing pad LP_P disposed at the same or substantially the same level as the cell landing pad LP and the peripheral capacitor DSP_P disposed at the same or substantially the same level as the cell capacitor DSP may be disposed in the cell array structure CS disposed in the peripheral circuit region PAR.

The peripheral landing pad LP_P disposed in the peripheral circuit region PAR may be disposed at the same or substantially the same level as the peripheral landing pad LP_P disposed in the cell array region CAR, and may be formed of and/or include the same material as the cell landing pad LP. For example, the cell landing pad LP and the peripheral landing pad LP_P may be disposed in the pad separation insulation layer 273.

This configuration may be a result of forming the peripheral landing pad LP_P during a process step of forming the cell landing pad LP. For example, in the step of forming the conductive material layer to form the cell landing pad LP in the cell array region CAR and the peripheral circuit region PAR, in order to form the cell landing pad LP in the cell array region CAR, the conductive material layer may be patterned to form the cell landing pad LP in the cell array region CAR and form the peripheral landing pad LP_P in the peripheral circuit region PAR.

The peripheral landing pad LP_P may be formed of and/or include a conductive material. The conductive material may include, for example, at least one of doped polysilicon, conductive metal nitride, conductive metal silicon nitride, metal carbonitride, conductive metal silicide, conductive metal oxide, a 2D material, and a metal.

The semiconductor device according to this embodiment may include the plurality of peripheral capacitors DSP_P. As shown in FIG. 7, the peripheral capacitors DSP_P may be arranged to be parallel to each other in peripheral circuit region PAR in the first direction X or the second direction Y. However, an arrangement shape of the peripheral capacitors DSP_P on the plane is not limited thereto and may be changed in various ways. For example, the peripheral capacitors DSP_P may be arranged in the matrix pattern in the first direction X and the second direction Y.

The peripheral capacitor DSP_P may completely or partially overlap the peripheral landing pad LP_P in the third direction Z. For example, the peripheral capacitor DSP_P may be in contact with the entire or partial upper surface of the peripheral landing pad LP_P.

Each peripheral capacitor DSP_P may include a peripheral lower electrode 251P, a peripheral upper electrode 255P, and a peripheral dielectric film 253P interposed between the peripheral lower electrode 251P and the peripheral upper electrode 255P.

The peripheral lower electrode 251P may have a variety of planar shapes such as the circular, oval, rectangular, square, diamond, and hexagonal shapes. The peripheral lower electrode 251P may penetrate through the contact etch stop layer 275 to be in contact with the peripheral landing pad LP_P. The peripheral lower electrode 251P may extend in the third direction Z, which is the vertical direction, on the peripheral landing pad LP_P.

In addition, the peripheral lower electrode 251P may be disposed at the same or substantially the same level as the cell lower electrode 251 disposed in the cell array region CAR and may be formed of and/or include the same material as the cell lower electrode 251.

The peripheral lower electrode 251P may be formed of and/or include a metal, a conductive metal nitride, or a combination thereof. For example, the peripheral lower electrode 251P may be made of titanium nitride (TiN), ruthenium (Ru), tantalum nitride (TaN), tungsten nitride (WN), platinum (Pt), Iridium (Ir), or a combination thereof.

The peripheral dielectric film 253P may be disposed conformally along profiles of the upper and side surfaces of the peripheral lower electrode 251P. For example, the peripheral dielectric film 253P may cover the side and upper surfaces of the peripheral lower electrode 251P. A portion of the peripheral dielectric film 253P may be disposed on the upper surface of the contact etch stop layer 275. For example, a portion of the peripheral dielectric film 253P may be disposed between the contact etch stop layer 275 and the peripheral upper electrode 255P.

In addition, the peripheral dielectric film 253P may be disposed at the same or substantially the same level as the cell dielectric film 253 disposed in the cell array region CAR and may be formed of and/or include the same material as the cell dielectric film 253.

The peripheral dielectric film 253P may be formed of and/or include tantalum oxide (Ta₂O₅), aluminum oxide (Al₂O₃), titanium oxide (TiO₂), or a combination thereof. However, the inventive concept is not limited thereto, and a material included in the peripheral dielectric film 253P may be changed in various ways.

The peripheral upper electrode 255P may be disposed on the peripheral dielectric film 253P. The peripheral upper electrode 255P may entirely cover the peripheral lower electrode 251P.

The peripheral upper electrode 255P may be formed of and/or include the metal material such as tungsten (W), titanium (Ti), ruthenium (Ru), or silicon germanium (SiGe). For example, the peripheral upper electrode 255P may be formed of and/or include tungsten (W). However, a material included in the peripheral upper electrode 255P is not limited thereto and may be changed in various ways. For example, the peripheral upper electrode 255P may be formed of and/or include conductive metal nitride, metal silicide, or a combination thereof.

This configuration may be a result of simultaneously forming the peripheral capacitor DSP_P in the peripheral circuit region PAR in a process step of forming the cell capacitor DSP in the cell array region CAR. For example, in the process step of sequentially forming the cell lower electrode 251, the cell dielectric film 253, and the cell upper electrode 255 in the cell array region CAR, the peripheral lower electrode 251P, the peripheral dielectric film 253P, and the peripheral upper electrode 255P may be formed simultaneously and/or sequentially in the peripheral circuit region PAR.

The peripheral upper electrode 255P disposed in the peripheral circuit region PAR may be disposed at the same or substantially the same level as the cell upper electrode 255 disposed in the cell array region CAR and may be formed of and/or include the same material as the cell upper electrode 255. However, a shape of the peripheral upper electrode 255P may be different from a shape of the cell upper electrode 255. For example, unlike the cell upper electrode 255, the peripheral upper electrode 255P may not include any protrusion disposed on the contact etch stop layer 275 and extending in the first direction X, which is the horizontal direction.

In detail, the peripheral upper electrode 255P may include a first part 255P_a covering an upper surface of the peripheral lower electrode 251P and extending in the first direction X which is the horizontal direction, and a second part 255P_b covering a side surface of peripheral lower electrode 251P and extending in the third direction Z. For example, unlike the cell upper electrode 255, the peripheral upper electrode 255P may not include the protrusion like the third part 255c of the cell upper electrode 255.

This configuration may from the peripheral upper electrode 255P being formed into the different shape in a step of forming the peripheral upper electrode 255P, for example, in the process step of patterning the conductive material layer in order to respectively form the cell upper electrode 255 and the peripheral upper electrode 255P in the cell array region CAR and the peripheral circuit region PAR.

According to an embodiment shown in FIG. 8, the peripheral upper electrode 255P may be sequentially electrically connected to the first upper wiring 262, the second upper contact plug 263, and the second upper wiring 264 through the upper conductive contact plug MC_T. The upper conductive contact plug MC_T may be connected to the first part 255P_a of the peripheral upper electrode 255P.

The peripheral lower electrode 251P may be electrically connected to the upper bonding pad 222 through the lower conductive contact plug MC_L connected to the peripheral landing pad LP_P. For example, the peripheral upper electrode 255P may be electrically connected to the upper bonding pad 222 through the lower wiring 232 and the lower contact plug 231 which are connected to the lower conductive contact plug MC_L.

The peripheral lower electrode 251P connected to the upper bonding pad 222 may be connected to the peripheral circuit wirings PCL1 and PCL2 and/or the peripheral circuit PC which are disposed in the peripheral circuit structure PS by the lower bonding pad 221. However, a connection relationship between the peripheral lower electrode 251P and the peripheral circuit structure PS is not limited thereto and may be changed in various ways.

In this embodiment, the peripheral capacitor DSP_P may be a decoupling capacitor. For example, as described above with reference to FIG. 5, the peripheral capacitor DSP_P disposed in the peripheral circuit region PAR may be connected to the first and second upper wirings 262 and 264, the peripheral wirings PCL1 and PCL2, and the peripheral circuit PC, which are disposed in the peripheral circuit structure PAR, or the like to thus prevent the rapid change in the various voltages applied to the respective components, thereby ensuring the stable supply of the voltage. For example, the peripheral capacitor DSP_P may remove the noise from the voltage applied to each component.

The semiconductor device according to an embodiment shown in FIG. 8 may achieve the same or substantially the same effect as the semiconductor device according to an embodiment shown in FIG. 5. However, the peripheral capacitor DSP_P according to this embodiment may have a different structure from that of the peripheral sub-capacitor C_{P} shown in FIG. 5. Accordingly, capacitance of the peripheral capacitor DSP_P according to this embodiment may be greater than that of the peripheral sub-capacitor C_{P} shown in FIG. 5.

An embodiment shown in FIG. 9 is different from an embodiment shown in FIG. 8 in that a connection position of the upper conductive contact plug MC_T is changed as the shape of the peripheral upper electrode 255P of the peripheral capacitor DSP_P is different from the shape of the peripheral upper electrode 255P of the peripheral capacitor DSP_P according to an embodiment shown in FIG. 8.

In detail, referring to FIG. 9, the peripheral upper electrode 255P of the peripheral capacitor DSP_P disposed in the peripheral circuit region PAR may have the same or substantially the same shape as the cell upper electrode 255 of the cell capacitor DSP disposed in the cell array region CAR.

In this embodiment, unlike the peripheral upper electrode 255P shown in FIG. 8, the peripheral upper electrode 255P of the peripheral capacitor DSP_P may extend from a side surface of the peripheral upper electrode 255P in the first direction X, which is horizontal to the substrate 200, and may include the protrusion disposed on the contact etch stop layer 275. For example, the protrusion of the peripheral upper electrode 255P may correspond to an end of the peripheral upper electrode 255P and the end of the peripheral upper electrode 255P may be disposed on the contact etch stop layer 275.

In more detail, unlike the peripheral upper electrode 255P shown in FIG. 8, the peripheral upper electrode 255P according to this embodiment may further include a third part 255P_c extending from a side surface of the second part 255P_b of the peripheral upper electrode 255P in the first direction X which is the horizontal direction and disposed on the contact etch stop layer 275.

According to this embodiment, as the peripheral upper electrode 255P further includes the third part 255P_c, the upper conductive contact plug MC_T connected to the peripheral upper electrode 255P may be connected to the third part 255P_c of the peripheral upper electrode 255P.

For example, in order to improve connection stability of the peripheral upper electrode 255P and the upper conductive contact plug MC_T and secure a process margin, the peripheral upper electrode 255P may have a relatively flat surface among the first to third parts 255P_a, 255P_b, and 255P_c, and the upper conductive contact plug MC_T may be connected to the third part 255P_c of the peripheral upper electrode 255P that has a relatively large area.

The semiconductor device according to an embodiment shown in FIG. 9 may achieve the same or substantially the same effect as the semiconductor device according to an embodiment shown in FIG. 8. Furthermore, the semiconductor device may secure improved reliability by stably connecting the upper conductive contact plug MC_T to the peripheral upper electrode 255P and achieve improved productivity by securing the process margin.

An embodiment shown in any of FIGS. 10 to 12 is different from an embodiment shown in any of FIGS. 1 to 3 in the different planar shape and arrangement shape of the conductive pad MP disposed in the peripheral circuit region PAR and a different configuration of the peripheral sub-capacitor C_{P}.

In detail, referring to FIG. 10, the peripheral circuit region may include a plurality of first conductive pads MP1 and a plurality of second conductive pads MP2, which are disposed in the peripheral circuit region PAR.

Unlike an embodiment shown in FIG. 1, each of the first conductive pad MP1 and the second conductive pad MP2 according to this embodiment may have a planar line shape. For example, each of the first conductive pad MP1 and the second conductive pad MP2 may include a vertical part extending in the second direction Y, which is the extension direction of the bit line BL, and a plurality of horizontal parts each extending from the vertical part to the first direction X, which is the extension direction of the word line WL. All the vertical and horizontal parts of each of the first conductive pad MP1 and the second conductive pad MP2 may each have the planar line shape.

The first conductive pad MP1 and the second conductive pad MP2 may be arranged alternately with each other on the plane to at least partially overlap each other. For example, the horizontal parts of the first conductive pad MP1 and the horizontal parts of the second conductive pad MP2 may be sequentially arranged alternately with each other in the second direction Y, which is the extension direction of the bit line BL.

Accordingly, the horizontal part of the first conductive pad MP1 and the horizontal part of the second conductive pad MP2 may be disposed to be parallel to each other in the horizontal direction, and the horizontal part of the first conductive pad MP1 and the horizontal part of the second conductive pad MP2 may at least partially overlap each other.

In addition, the vertical part of the first conductive pad MP1 and the vertical part of the second conductive pad MP2 may each be disposed at each of two ends of the horizontal part of the first conductive pad MP1 and the horizontal part of the second conductive pad MP2. Accordingly, each end of the horizontal parts of the first conductive pad MP1 may face the vertical part of the second conductive pad MP2 and each end of the horizontal parts of the second conductive pad MP2 may face the vertical part of the first conductive pad MP1. However, the arrangement shape of the plurality of first conductive pads MP1 and the arrangement shape of the plurality of second conductive pads MP2, each having the planar line shape, are not limited thereto, and may be changed in various ways.

FIG. 10 shows that the first conductive pad MP1 and the second conductive pad MP2 are disposed in the peripheral circuit region PAR disposed at each of the two ends of the bit line BL. However, the disposition of each of the first conductive pad MP1 and the second conductive pad MP2 disposed in the peripheral circuit region PAR is not limited to this placement and may be changed in various ways. For example, the plurality of first conductive pad MP1 and the plurality of second conductive pad MP2, each having the planar line shape, May be further disposed in at least one of the peripheral circuit regions PAR disposed at the two ends of the word line WL.

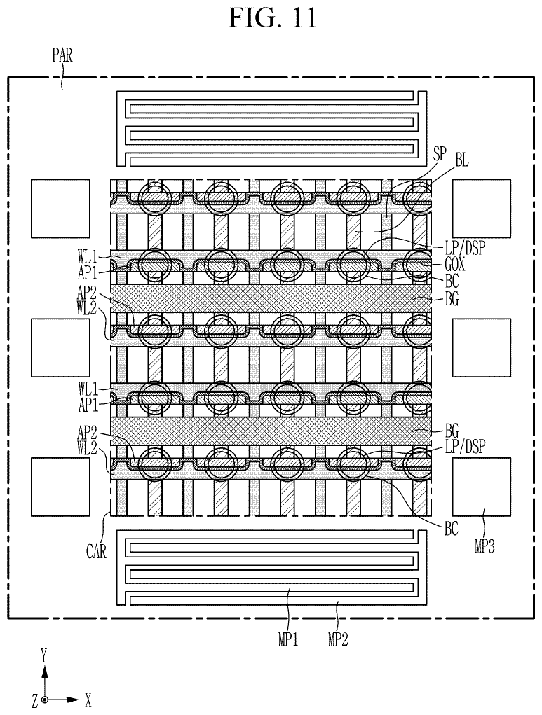

In addition, in some embodiments, as shown in FIG. 11, a plurality of third conductive pads MP3 arranged in the planar island shape may be further disposed in the peripheral circuit region PAR disposed at each of two ends of the word line WL. The plurality of third conductive pads MP3 may be arranged to the parallel to each other in the second direction Y which is the extension direction of the bit line BL.

The plurality of third conductive pads MP3 disposed in the peripheral circuit region PAR disposed at each of two ends of the word line WL may have the same or substantially the same structure, connection relationship, and function as the conductive pad MP described above with reference to FIGS. 3 to 6.

Referring to FIG. 12 together with FIG. 10, each of the first conductive pad MP1 and the second conductive pad MP2 disposed in the cell array structure CS disposed in the peripheral circuit region PAR may be disposed at the same or substantially the same level as the third part 255c of the cell upper electrode 255 of the cell capacitor DSP disposed in the cell array region CAR and may be formed of and/or include the same material as the cell upper electrode 255.

The first conductive pad MP1 and the second conductive pad MP2 may be disposed on the contact etch stop layer 275 while being parallel to each other in the first direction X. For example, the first conductive pad MP1 and the second conductive pad MP2 may be disposed to be spaced apart from each other in the first direction X, and the first upper insulation layer 277 may be disposed between the first conductive pad MP1 and the second conductive pad MP2. For example, one side surface of the first conductive pad MP1 and one side surface of the second conductive pad MP2 may oppose and overlap each other while having the first upper insulation layer 277 therebetween.

A thickness of the first conductive pad MP1 in the third direction Z and a thickness of the second conductive pad MP2 in the third direction Z may each be the same or substantially the same as the thickness of the third part 255c of the cell upper electrode 255 in the vertical direction. However, a relationship between the thickness of the first conductive pad MP1 in the third direction Z and the thickness of the second conductive pad MP2 in the third direction Z is not limited thereto and may be changed in various ways.

For example, the thickness of the first conductive pad MP1 in the third direction Z and the thickness of the second conductive pad MP2 in the third direction Z may each be different from the thickness of the third part 255c of the cell upper electrode 255 in the vertical direction. As another example, the thickness of the first conductive pad MP1 in the third direction Z and the thickness of the second conductive pad MP2 in the third direction Z may be different from each other.

The semiconductor device according to this embodiment may include a first upper conductive contact plug MC_T1 and the first lower conductive contact plug MC_L1 each connected to the first conductive pad MP1, and a second upper conductive contact plug MC_T2 and the second lower conductive contact plug MC_L2 each connected to the second conductive pad MP2.

A connection relationship between the first upper conductive contact plug MC_T1 and the first conductive pad MP1, a connection relationship between the first lower conductive contact plug MC_L1 and the first conductive pad MP1, and a connection relationship between the first conductive pad MP1 and the cell capacitor DSP which is disposed in the cell array region CAR are the same or substantially the same as the connection relationship between the upper conductive contact plug MC_T and the conductive pad MP, the connection relationship between the lower conductive contact plug MC_L and the conductive pad MP, and the connection relationship between the conductive pad MP and the cell capacitor DSP which is disposed in cell array region CAR as described above with reference to FIG. 3, and their descriptions are thus omitted.

The second upper conductive contact plug MC_T2 may connect the second conductive pad MP2 and the first upper wiring 262 to each other. The second conductive pad MP2 may be sequentially electrically connected to the first upper wiring 262, the second upper contact plug 263, and the second upper wiring 264 through the second upper conductive contact plug MC_T2.

Here, the first upper wiring 262, the second upper contact plug 263, and the second upper wiring 264, which are connected to the second conductive pad MP2, may be different wirings and contact plug from the first upper wiring 262, the second upper contact plug 263, and the second upper wiring 264, which are connected to the first conductive pad MP1.

The second conductive pad MP2 connected to the second lower conductive contact plug MC_L2 may be connected to the second peripheral circuit wiring PCL2, other than the second peripheral circuit wiring PCL2 electrically connected to the first conductive pad MP1, through the upper bonding pad 222, the lower bonding pad 221, and the third peripheral contact plug PCT3.

For example, the second peripheral circuit wiring PCL2 electrically connected to the second conductive pad MP2 through the second lower conductive contact plug MC_L1 may be the different wiring from the second peripheral circuit wiring PCL2 electrically connected to the first conductive pad MP1 through the first lower conductive contact plug MC_L1. However, this configuration is an example, and a connection relationship between the first conductive pad MP1, the second conductive pad MP2, and the peripheral circuit wirings PCL1 and PCL2 and/or the peripheral circuit PC, which are included in the peripheral circuit structure PS, may be changed in various ways.

In this embodiment, each of the first conductive pad MP1 and the second conductive pad MP2 may serve as the power transmission wiring connected to the power wiring to which the external voltage is applied. However, this configuration is an example, and functions of the first conductive pad MP1 and the second conductive pad MP2 are not limited thereto and may be changed in various ways. For example, the second conductive pad MP2 may be the signal transmission wiring as described above with reference to FIG. 4.

In this embodiment, the peripheral sub-capacitor C_{P} may be formed by including the first conductive pad MP1 and the second conductive pad MP2 facing each other in the first direction X, which is horizontal to the substrate 200, and the first upper insulation layer 277 disposed between the first conductive pad MP1 and the second conductive pad MP2.

For example, the first conductive pad MP to which the first voltage is applied through the first upper conductive contact plug MC_T1 may function as the first electrode, the second conductive pad MP2 to which the second voltage different from the first voltage is applied through the second upper conductive contact plug MC_T2 may function as the second electrode, and a portion of the first upper insulation layer 277 disposed between the first conductive pad MP1 and the second conductive pad MP2 may function as the dielectric. For example, the peripheral sub-capacitor C_{P} may be the metal-insulator-metal (MIM) capacitor including the first conductive pad MP1, the second conductive pad MP2, and a portion of the first upper insulation layer 277.

The peripheral sub-capacitor C_{P} according to this embodiment may have a different configuration from that of the peripheral sub-capacitor C_{P} described above with reference to FIG. 5 and may perform the same or substantially the same function as the peripheral sub-capacitor C_{P} of FIG. 5.

The semiconductor device according to an embodiment shown in FIG. 12 may achieve the same or substantially the same effect as the semiconductor device according to an embodiment shown in FIG. 5. In addition, the semiconductor devices may achieve increased integration and secure the improved electrical feature by disposing the metal-insulator-metal (MIM) capacitor including the first conductive pad MP1 and the second conductive pad MP2, which serve as the power transmission wiring and/or the signal transmission wiring, in the peripheral circuit region PAR.

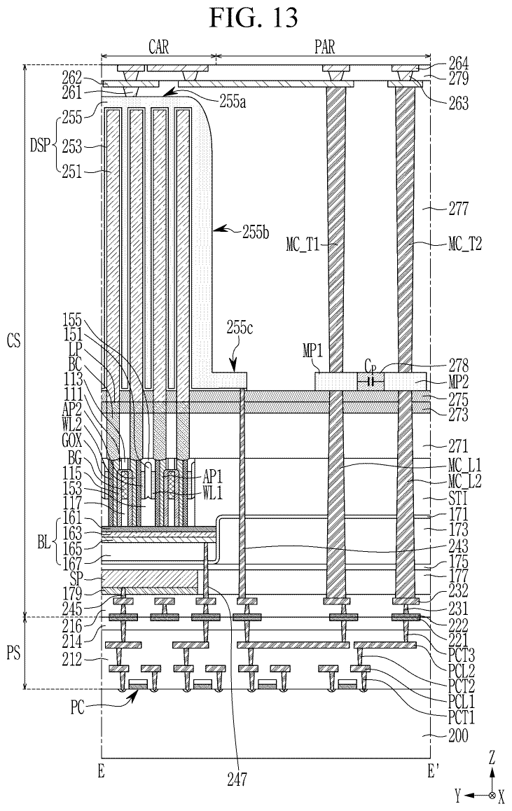

An embodiment shown in FIG. 13 is different from an embodiment shown in FIG. 12 in further including a third upper insulation layer 278 disposed between the first conductive pad MP1 and the second conductive pad MP2 in peripheral circuit region PAR.

In detail, referring to FIG. 13, the third upper insulation layer 278 may be further disposed between the first conductive pad MP1 and the second conductive pad MP2 overlapping each other in the first direction X, which is the horizontal direction, in the peripheral circuit region PAR. For example, the third upper insulation layer 278 may be disposed between one side surface of the first conductive pad MP1 and one side surface of the second conductive pad MP2 that face each other in the peripheral circuit region PAR, and the first conductive pad MP1, the third upper insulation layer 278, and the second conductive pad MP2 may be disposed at the same or substantially the same level as one another.

The first upper insulation layer 277 may entirely cover the first conductive pad MP1, the third upper insulation layer 278, and the second conductive pad MP2. For example, the first upper insulation layer 277 may cover the side and upper surfaces of the first conductive pad MP1, an upper surface of the third upper insulation layer 278, and the side and upper surfaces of the second conductive pad MP2.

The first upper insulation layer 277 and the third upper insulation layer 278 may be formed by separate process steps. For example, the third upper insulation layer 278 may be formed between the first conductive pad MP1 and the second conductive pad MP2, and the first upper insulation layer 277 may then be formed to entirely cover the first conductive pad MP1, the third upper insulation layer 278, and the second conductive pad MP2.

FIG. 13 shows that a thickness of the third upper insulation layer 278 is the same or substantially the same as the thickness of the first conductive pad MP1 and the thickness of the second conductive pad MP2, and is not limited to thereto in embodiments of the inventive concept. For example, the thickness of the third upper insulation layer 278 may be different from the thickness of the first conductive pad MP1 or the thickness of the second conductive pad MP2.

In an embodiment, the first upper insulation layer 277 and the third upper insulation layer 278 may be formed of and/or include materials different from each other. The third upper insulation layer 278 may be formed of and/or include a material with a relatively high-k compared to the first upper insulation layer 277. For example, the high-k material may include oxide including one or more of titanium (Ti), tantalum (Ta), niobium (Nb), lanthanum (La), barium (Ba), strontium (Sr), yttrium (Y), and lutetium (Lu). However, the high-k material is not limited thereto and may be changed in various ways.

Accordingly, the third upper insulation layer 278 may have a dielectric constant higher than that of the first upper insulation layer 277.

In this embodiment, the peripheral sub-capacitor C_{P} may be formed by including the first conductive pad MP1 and the second conductive pad MP2 facing each other in the first direction X which is the horizontal direction, and the third upper insulation layer 278 disposed between the first conductive pad MP1 and the second conductive pad MP2. The third upper insulation layer 278 disposed between the first conductive pad MP1 and the second conductive pad MP2 may function as the dielectric. For example, compared to an embodiment shown in FIG. 12, the third upper insulation layer 278 with the relatively high-k may be formed between the first conductive pad MP1 and the second conductive pad MP2 to thus increase the capacitance of the peripheral sub-capacitor C_{P}.

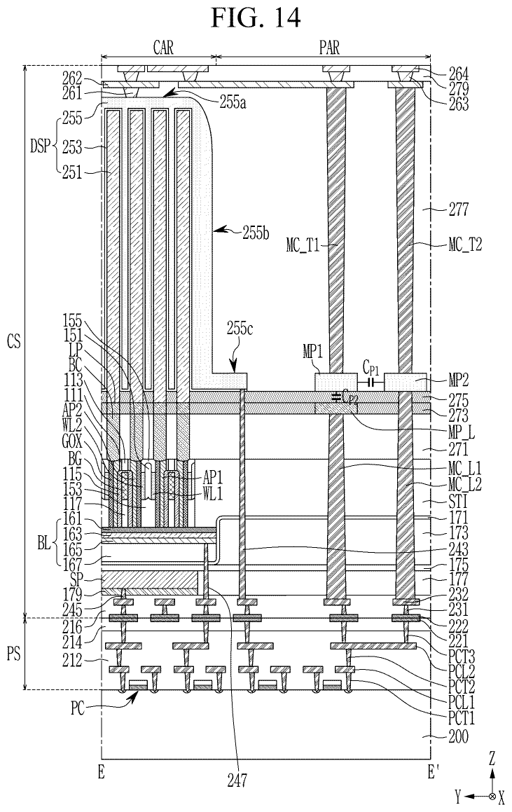

An embodiment shown in FIG. 14 may be different from an embodiment shown in FIG. 12 in that the additional conductive pad MP_L other than the conductive pad MP is further disposed in the peripheral circuit region PAR, and accordingly, a second peripheral sub-capacitor C_{P2} including the first conductive pad MP1 and the additional conductive pad MP_L is further disposed.

In detail, referring to FIG. 14, the first conductive pad MP1 and the second conductive pad MP2 may be disposed on the contact etch stop layer 275 while being parallel to each other in the first direction X. For example, the first conductive pad MP1 and the second conductive pad MP2 may be disposed to be spaced apart from each other in the first direction X, and the first upper insulation layer 277 may be disposed between the first conductive pad MP1 and the second conductive pad MP2. For example, one side surface of the first conductive pad MP1 and one side surface of the second conductive pad MP2 may oppose and overlap each other while having the first upper insulation layer 277 therebetween.

The additional conductive pad MP_L in the peripheral circuit region PAR may be formed of and/or include the same material as the cell landing pad LP disposed in the cell array region CAR and may be disposed at the same or substantially the same level as the cell landing pad LP. For example, the additional conductive pad MP_L disposed in the peripheral circuit region PAR may be disposed in the pad separation insulation layer 273 like the cell landing pad LP disposed in the cell array region CAR.

In the peripheral circuit region PAR, the additional conductive pad MP_L and the first conductive pad MP1 may be disposed so that at least their portions overlap each other in the third direction Z which is the vertical direction. For example, the additional conductive pad MP_L may be disposed under the first conductive pad MP1 and these two pads may be spaced apart from each other while having the contact etch stop layer 275 therebetween. For example, the upper surface of the additional conductive pad MP_L and the lower surface of the first conductive pad MP1 may face each other while having the contact etch stop layer 275 therebetween.

The semiconductor device according to this embodiment may include the first upper conductive contact plug MC_T1 connected to the first conductive pad MP1, the first lower conductive contact plug MC_L1 connected to the additional conductive pad MP_L, and the second upper conductive contact plug MC_T2 and the second lower conductive contact plug MC_L2 each connected to the second conductive pad MP2.

The first upper conductive contact plug MC_T1 may connect the first conductive pad MP1 and the first upper wiring 262 to each other. The first conductive pad MP1 may be sequentially electrically connected to the first upper wiring 262, the second upper contact plug 263, and the second upper wiring 264 through the first upper conductive contact plug MC_T1.

The second upper conductive contact plug MC_T2 may connect the second conductive pad MP2 and the first upper wiring 262 to each other. The second conductive pad MP2 may be sequentially electrically connected to the first upper wiring 262, the second upper contact plug 263, and the second upper wiring 264 through the second upper conductive contact plug MC_T2.

Here, the first upper wiring 262, the second upper contact plug 263, and the second upper wiring 264, which are connected to the second conductive pad MP2, may be different wirings and contact plug from the first upper wiring 262, the second upper contact plug 263, and the second upper wiring 264, which are connected to the first conductive pad MP1.

The first lower conductive contact plug MC_L1 may connect the additional conductive pad MP_L and the upper bonding pad 222 to each other. For example, the additional conductive pad MP_L may be electrically connected to the upper bonding pad 222 through the lower wiring 232 and the lower contact plug 231 which are connected to the first lower conductive contact plug MC_L1.

The additional conductive pad MP_L connected to the upper bonding pad 222 may be connected to the peripheral circuit wirings PCL1 and PCL2 and/or the peripheral circuit PC which are disposed in the peripheral circuit structure PS by the lower bonding pad 221.

The second conductive pad MP2 electrically connected to the second lower conductive contact plug MC_L2 may be electrically connected to the second peripheral circuit wiring PCL2 electrically connected to the additional conductive pad MP_L through the upper bonding pad 222, the lower bonding pad 221, and the third peripheral contact plug PCT3. For example, the second peripheral circuit wiring PCL2 electrically connected to the second conductive pad MP2 through the second lower conductive contact plug MC_L2 may be the same wiring from the second peripheral circuit wiring PCL2 electrically connected to the additional conductive pad MP_L through the first lower conductive contact plug MC_L1. However, this configuration is an example, and a connection relationship between the first conductive pad MP1, the second conductive pad MP2, the additional conductive pad MP_L, and the peripheral circuit wirings PCL1 and PCL2 and/or the peripheral circuit PC, which are included in the peripheral circuit structure PS, may be changed in various ways.

Accordingly, the same voltage may be applied to the second upper conductive contact plug MC_T2, second conductive pad MP2, and the first and second lower conductive contact plugs MC_L1 and MC_L2.

In this embodiment, a first peripheral sub-capacitor C_{P1} may be formed by including the first conductive pad MP1 and the second conductive pad MP2 facing each other in the first direction X which is horizontal to the substrate 200, and the first upper insulation layer 277 disposed between the first conductive pad MP1 and the second conductive pad MP2.

For example, the first conductive pad MP1 to which the first voltage is applied through the first upper conductive contact plug MC_T1 may function as the first electrode, the second conductive pad MP2 to which the second voltage different from the first voltage is applied through the second upper conductive contact plug MC_T2 may function as the second electrode, and a portion of the first upper insulation layer 277 disposed between the first conductive pad MP1 and the second conductive pad MP2 may function as the dielectric. For example, the first peripheral sub-capacitor C_{P1} may be the metal-insulator-metal (MIM) capacitor including the first conductive pad MP1, the second conductive pad MP2, and a portion of the first upper insulation layer 277.

In this embodiment, the second peripheral sub-capacitor C_{P2} may be formed by including the additional conductive pad MP_L and the first conductive pad MP1 facing each other in the third direction Z which is the vertical direction, and the contact etch stop layer 275 disposed between the additional conductive pad MP_L and the first conductive pad MP1. For example, the first conductive pad MP1 to which the first voltage is applied through the first upper conductive contact plug MC_T1 may function as the first electrode, the additional conductive pad MP_L to which the second voltage different from the first voltage is applied through the first lower conductive contact plug MC_L1 may function as the second electrode, and a portion of the contact etch stop layer 275 disposed between the first conductive pad MP1 and the additional conductive pad MP_L may function as the dielectric. For example, the second peripheral sub-capacitor C_{P2} may be the metal-insulator-metal (MIM) capacitor including the additional conductive pad MP_L, the first conductive pad MP1, and a portion of the contact etch stop layer 275.

The semiconductor device according to an embodiment shown in FIG. 14 may achieve the same or substantially the same effect as the semiconductor device according to an embodiment shown in FIG. 12. However, unlike an embodiment shown in FIG. 12, the semiconductor device according to this embodiment may have a relatively high capacitance as the second peripheral sub-capacitor C_{P2} is further disposed in the peripheral circuit region PAR compared to the case where one peripheral sub-capacitor C_{P} is disposed in the peripheral circuit region PAR.

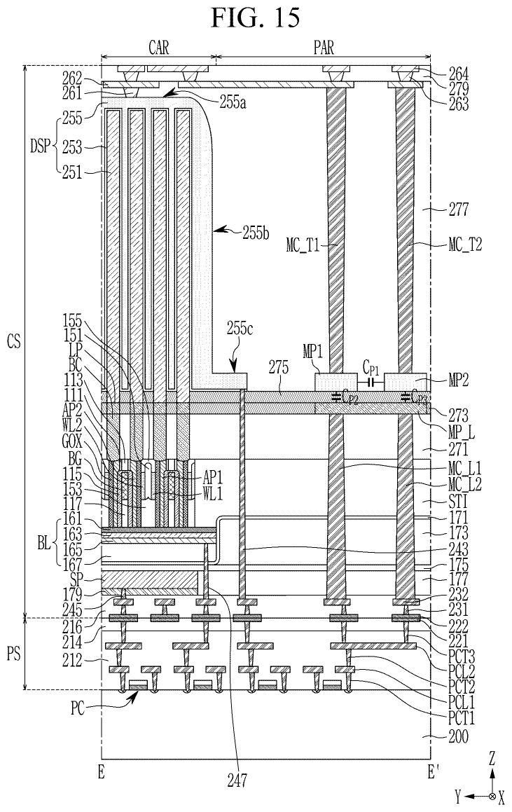

An embodiment shown in FIG. 15 may be different from an embodiment shown in FIG. 14 in that a third peripheral sub-capacitor C_{P3} including the additional conductive pad MP_L and the second conductive pad MP2 is further disposed due to a different arrangement relationship between the additional conductive pad MP_L and the second conductive pad MP2 in the peripheral circuit region PAR.

In detail, referring to FIG. 15, in the peripheral circuit region PAR, the additional conductive pad MP_L may overlap the first conductive pad MP1 and the second conductive pad MP2 in the third direction Z which is the vertical direction. For example, the additional conductive pad MP_L may extend in the pad separation insulation layer 273 in the first direction X, which is the horizontal direction, and may overlap the first conductive pad MP1 and the second conductive pad MP2 while being spaced apart from the pads while having the contact etch stop layer 275 therebetween.

FIG. 15 shows that a portion of one additional conductive pad MP_L overlaps the first conductive pad MP1 and the second conductive pad MP2 in the third direction Z which is the vertical direction, and the other portion of the additional conductive pad MP_L does not overlap the first conductive pad MP1 or the second conductive pad MP2 in the vertical direction. However, an overlap relationship between the additional conductive pad MP_L, the first conductive pad MP1, and the second conductive pad MP2 is not limited thereto and may be changed in various ways.

For example, in some embodiments, the semiconductor device may include the plurality of additional conductive pads MP_L, the plurality of additional conductive pads MP_L may each be disposed to overlap the first conductive pad MP1 and the second conductive pad MP2 in the pad separation insulation layer 273 in the third direction Z which is the vertical direction, and disposed not to overlap the same in a region between the first conductive pad MP1 and the second conductive pad MP2 in the third direction Z which is the vertical direction.

In this embodiment, the second lower conductive contact plug MC_L2 may connect the additional conductive pad MP_L and the upper bonding pad 222 to each other, unlike the case where the second lower conductive contact plug MC_L2 connects the second conductive pad MP2 and the upper bonding pad 222 to each other in an embodiment shown in FIG. 14. For example, the additional conductive pad MP_L may be electrically connected to the upper bonding pad 222 through the lower wiring 232 and the lower contact plug 231 which are connected to the second lower conductive contact plug MC_L2.

The additional conductive pad MP_L connected to the upper bonding pad 222 may be connected to the peripheral circuit wirings PCL1 and PCL2 and/or the peripheral circuit PC which are disposed in the peripheral circuit structure PS by the lower bonding pad 221.

Here, the additional conductive pad MP_L electrically connected to the second lower conductive contact plug MC_L2 may be electrically connected to the second peripheral circuit wiring PCL2 electrically connected to the additional conductive pad MP_L through the upper bonding pad 222, the lower bonding pad 221, and the third peripheral contact plug PCT3. For example, the second peripheral circuit wiring PCL2 electrically connected to the additional conductive pad MP_L through the second lower conductive contact plug MC_L2 may be the same wiring as the second peripheral circuit wiring PCL2 electrically connected to the additional conductive pad MP_L through the first lower conductive contact plug MC_L1. However, this configuration is an example, and a connection relationship between the additional conductive pad MP_L and the peripheral circuit wirings PCL1 and PCL2 and/or the peripheral circuit PC, which are included in the peripheral circuit structure PS, may be changed in various ways.

According to this embodiment, the semiconductor device may further include the third peripheral sub-capacitor C_{P3} including the additional conductive pad MP_L and the second conductive pad MP2 facing each other in the third direction Z, which is the vertical direction, and the contact etch stop layer 275 disposed between the additional conductive pad MP_L and the second conductive pad MP2 as the additional conductive pad MP_L overlaps the second conductive pad MP2 in the peripheral circuit region PAR in the third direction Z which is the vertical direction.

Like the first peripheral sub-capacitor C_{P1} and the second peripheral sub-capacitor C_{P2}, the third peripheral sub-capacitor C_{P3} may be a metal-insulator-metal (MIM) capacitor including the additional conductive pad MP_L, the second conductive pad MP2, and a portion of the contact etch stop layer 275.

The semiconductor device according to an embodiment shown in FIG. 15 may achieve the same or substantially the same effect as the semiconductor device according to an embodiment shown in FIG. 14. However, unlike an embodiment shown in FIG. 14, the semiconductor device according to this embodiment may have a relatively high capacitance as the third peripheral sub-capacitor C_{P3} is further disposed in the peripheral circuit region PAR compared to the case where the two peripheral sub-capacitors C_{P1} and C_{P2} are disposed in the peripheral circuit region PAR.

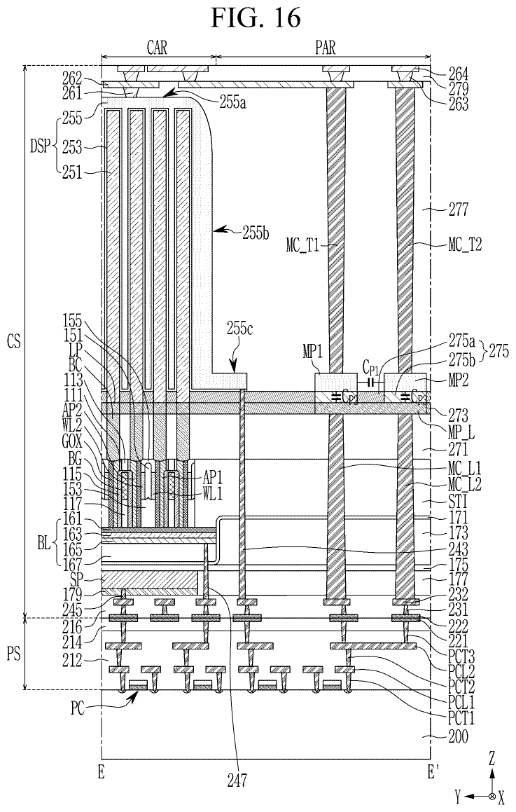

An embodiment shown in FIG. 16 may be different from an embodiment shown in FIG. 15 in that the contact etch stop layer 275 includes the first contact etch stop layers 275a and the second contact etch stop layers 275b respectively disposed between the first conductive pad MP1 and the additional conductive pad MP_L, and between the second conductive pad MP2 and the additional conductive pad MP_L, in the peripheral circuit region PAR.

In detail, referring to FIG. 16, in the cell array region CAR and the peripheral circuit region PAR, the first contact etch stop layers 275a may be disposed in a region where the first conductive pad MP1 and the additional conductive pad MP_L do not overlap each other in the third direction Z, which is the vertical direction, and a region where the second conductive pad MP2 and the additional conductive pad MP_L do not overlap each other in the third direction Z, which is the vertical direction, and the second contact etch stop layer 275b may be disposed in a region where the first conductive pad MP1 and the additional conductive pad MP_L overlap each other in the third direction Z, which is the vertical direction, and a region where the second conductive pad MP2 and the additional conductive pad MP_L overlap each other in the third direction Z, which is the vertical direction.

For example, in the peripheral circuit region PAR, the second contact etch stop layers 275b may be disposed between the first conductive pad MP1 and the additional conductive pad MP_L, and between the second conductive pad MP2 and the additional conductive pad MP_L. For example, the first contact etch stop layer 275a may not overlap the first conductive pad MP1, the second conductive pad MP2, or the additional conductive pad MP_L, and the second contact etch stop layer 275b may overlap the first conductive pad MP1, the second conductive pad MP2, and the additional conductive pad MP_L in the third direction Z, which is the vertical direction.

Accordingly, in the cell array region CAR and the peripheral circuit region PAR, the first contact etch stop layer 275a and the second contact etch stop layer 275b may be disposed at the same or substantially the same level as each other.

In an embodiment, the first contact etch stop layer 275a and the second contact etch stop layer 275b may be formed of and/or include the materials different from each other. The second contact etch stop layer 275b may be formed of and/or include a material with a relatively high-k compared to the first contact etch stop layer 275a. For example, the high-k material may include oxide including one or more of titanium (Ti), tantalum (Ta), niobium (Nb), lanthanum (La), barium (Ba), strontium (Sr), yttrium (Y), and lutetium (Lu). However, the high-k material is not limited thereto and may be changed in various ways.

Accordingly, the second contact etch stop layer 275b may have a dielectric constant higher than that of the first contact etch stop layer 275a.

In this embodiment, the first peripheral sub-capacitor C_{P1} may be formed by including the additional conductive pad MP_L and the first conductive pad MP1 facing each other in the third direction Z, which is the vertical direction, and the second contact etch stop layer 275b disposed between the additional conductive pad MP_L and the first conductive pad MP1.

In addition, the third peripheral sub-capacitor C_{P3} may be formed by including the additional conductive pad MP_L and the second conductive pad MP2 facing each other in the third direction Z, which is the vertical direction, and the second contact etch stop layer 275b disposed between the additional conductive pad MP_L and the second conductive pad MP2.

As described above, each of the second contact etch stop layers 275b disposed between the first conductive pad MP1 and the additional conductive pad MP_L, and between the second conductive pad MP2 and the additional conductive pad MP_L may function as the dielectric. According to this embodiment, compared to an embodiment shown in FIG. 15, the second contact etch stop layers 275b each having the relatively high-k is formed between the first conductive pad MP1 and the additional conductive pad MP_L, and between the second conductive pad MP2 and the additional conductive pad MP_L, thereby increasing each capacitance of the second and third peripheral sub-capacitors C_{P2} and C_{P3}.

Although the embodiments of the present disclosure have been described in detail hereinabove, the scope of the inventive concept is not limited thereto, and may include several modifications and alterations made by those skilled in the art using the inventive concept as defined in the claims.

What is claimed is:

1. A semiconductor device comprising:
a substrate having a first portion in a cell array region and a second portion in a peripheral circuit region;
a peripheral circuit structure including a peripheral circuit disposed on the substrate and peripheral circuit wiring connected to the peripheral circuit; and
a cell array structure disposed on the peripheral circuit structure,
wherein the cell array structure in the cell array region includes
a plurality of bit lines disposed on the peripheral circuit structure and extending in a first direction,
a plurality of word lines extending on the plurality of bit lines in a second direction that is different than the first direction,
an active pattern disposed between a first word line and a second word line of the plurality of word lines,
a cell landing pad connected to the active pattern, and
a cell capacitor disposed on the cell landing pad, and
the cell array structure in the peripheral circuit region includes
at least one conductive pad including the same material as the cell capacitor and disposed with a lower surface of the conductive pad at the same level as a lower end of the cell capacitor, and
a lower conductive contact plug connecting the conductive pad and the peripheral circuit structure to each other.

2. The device of claim 1, wherein
the cell capacitor includes a cell lower electrode connected to the cell landing pad,
a cell upper electrode covering the cell lower electrode, and
a cell dielectric film disposed between the cell lower electrode and the cell upper electrode,
wherein the cell upper electrode and the conductive pad include the same material, and the cell upper electrode includes
a first part covering an upper surface of the cell lower electrode,
a second part covering a side surface of the cell lower electrode, and
a third part extending from the second part in a horizontal direction, and
wherein the third part of the cell upper electrode is disposed at the same level as the conductive pad.

3. The device of claim 2, wherein
each of the cell upper electrode and the conductive pad includes tungsten (W).

4. The device of claim 1, further comprising:
upper wiring disposed on the cell capacitor;
an upper conductive contact plug connecting the upper wiring and the conductive pad to each other;
a capacitor contact plug connecting the cell capacitor and the peripheral circuit structure to each other, and
a bonding pad disposed on a boundary between the peripheral circuit structure and the cell array structure,
wherein the lower conductive contact plug is electrically connected to the peripheral circuit wiring through the bonding pad, and
the lower conductive contact plug and the capacitor contact plug are electrically connected to each other through the peripheral circuit wiring.

5. The device of claim 4, wherein:
a length of the upper conductive contact plug in a vertical direction is longer than a length of the lower conductive contact plug in the vertical direction.

6. The device of claim 1, wherein the lower conductive contact plug is a first lower conductive contact plug, the device further comprising:
a second lower conductive contact plug that connects the conductive pad and the peripheral circuit structure,
wherein the first lower conductive contact plug and the second lower conductive contact plug are respectively connected with different peripheral circuit wirings among the peripheral circuit wirings.

7. The device of claim 1, further comprising a plurality of conductive pads including the conductive pad, wherein:
the conductive pads of the plurality of conductive pads are arranged in an island shape on a plane.

8. A semiconductor device comprising:
a substrate having a first portion in a cell array region and a second portion in a peripheral circuit region;
a peripheral circuit structure including a peripheral circuit disposed on the substrate and peripheral circuit wiring connected to the peripheral circuit; and
a cell array structure disposed on the peripheral circuit structure,
wherein the cell array structure in the cell array region includes
a plurality of bit lines disposed on the peripheral circuit structure and extending in a first direction,
a plurality of word lines extending on the plurality of bit lines in a second direction that is different than the first direction,
an active pattern disposed between a first word line and a second word line of the plurality of word lines,
a cell landing pad connected to the active pattern, and
a cell capacitor disposed on the cell landing pad,
werein the the cell array structure in the peripheral circuit region includes
a peripheral landing pad including the same material as the cell landing pad and disposed at the same level as the cell landing pad,
at least one peripheral capacitor disposed at the same level as the cell capacitor and disposed on the peripheral landing pad,
an upper wiring disposed on the peripheral capacitor,
an upper conductive contact plug connecting the peripheral capacitor and the upper wiring to each other, and
a lower conductive contact plug connecting the peripheral landing pad and the peripheral circuit structure to each other, and
wherein the peripheral capacitor includes
a peripheral lower electrode connected to the peripheral landing pad,
a peripheral upper electrode covering the peripheral lower electrode, and
a peripheral dielectric film disposed between the peripheral lower electrode and the peripheral upper electrode.

9. The device of claim 8, wherein
the cell capacitor includes a cell lower electrode connected to the cell landing pad and that includes the same material as the peripheral lower electrode,
a cell upper electrode covering the cell lower electrode and that includes the same material as the peripheral upper electrode, and
a cell dielectric film disposed between the cell lower electrode and the cell upper electrode and that includes the same material as the peripheral dielectric film.

10. The device of claim 9, further comprising a bonding pad disposed at a boundary between the peripheral circuit structure and the cell array structure,
wherein the lower conductive contact plug is electrically connected with the peripheral circuit wiring through the bonding pad.

11. The device of claim 10, wherein the peripheral upper electrode comprises:
a first portion covering an upper surface of the peripheral lower electrode; and
a second portion covering side surfaces of the peripheral lower electrode, and
the upper conductive contact plug is connected with the first portion of the peripheral upper electrode.

12. The device of claim 10, wherein:
the peripheral upper electrode comprises:
a first portion covering an upper surface of the peripheral lower electrode;
a second portion covering side surfaces of the peripheral lower electrode; and
a third portion extending in a horizontal direction from the second portion, and
the upper conductive contact plug is connected with the third portion of the peripheral upper electrode.

13. A semiconductor device comprising:
a substrate having a first portion in a cell array region and a second portion in a peripheral circuit region;
a peripheral circuit structure including a peripheral circuit disposed on the substrate and peripheral circuit wiring connected to the peripheral circuit; and
a cell array structure disposed on the peripheral circuit structure,
wherein the cell array structure in the cell array region includes
a plurality of bit lines disposed on the peripheral circuit structure and extending in a first direction,
a plurality of word lines extending on the plurality of bit lines in a second direction that is different than the first direction,
an active pattern disposed between a first word line and a second word line of the plurality of word lines,
a cell landing pad connected to the active pattern, and
a cell capacitor disposed on the cell landing pad,
wherein the cell array structure in the peripheral circuit region includes
a first conductive pad and a second conductive pad each disposed at the same level as an end of the cell capacitor, and
an upper insulation layer covering the first conductive pad and the second conductive pad, and disposed between the first conductive pad and the second conductive pad,
each of the first conductive pad and the second conductive pad has a planar line shape on a plane,
the first conductive pad and the second conductive pad are arranged alternately with each other to at least partially overlap each other, and
a first peripheral sub-capacitor is configured to the first conductive pad, the second conductive pad, and the upper insulation layer.

14. The device of claim 13, wherein
the cell capacitor includes
a cell lower electrode connected to the cell landing pad,
a cell upper electrode covering the cell lower electrode, and
a cell dielectric film disposed between the cell lower electrode and the cell upper electrode,
wherein the cell upper electrode includes the same material as the first conductive pad and the second conductive pad,
wherein the cell upper electrode includes
a first part covering an upper surface of the cell lower electrode,
a second part covering a side surface of the cell lower electrode, and
a third part extending from the second part in a horizontal direction, and
wherein the third part of the cell upper electrode is disposed at the same level as the first conductive pad and the second conductive pad.

15. The device of claim 14, wherein:
the cell upper electrode, the first conductive pad, and the second conductive pad contain tungsten (W).

16. The device of claim 14, wherein:
the upper insulation layer comprises:
a first upper insulation layer disposed between the first conductive pad and the second conductive pad; and
a second upper insulation layer covering the first conductive pad, the second conductive pad, and the first upper insulation layer, and
a dielectric constant of the first upper insulation layer is higher than a dielectric constant of the second upper insulation layer.

17. The device of claim 14, further comprising in the peripheral circuit region:
an additional conductive pad disposed at the same level as the cell landing pad and including the same material as the cell landing pad; and
an etch stop layer disposed between the first conductive pad and the additional conductive pad,
wherein the first conductive pad and the additional conductive pad at least partially overlap each other in a vertical direction with the etch stop layer interposed therebetween, and
a second peripheral sub-capacitor is configured to the first conductive pad, the additional conductive pad, and the etch stop layer.

18. The device of claim 17, further comprising in the peripheral circuit region,:
a first upper wiring and a second upper wiring each disposed on the upper insulation layer;
a first upper conductive contact plug connecting the first upper wiring and the first conductive pad to each other;
a second upper conductive contact plug connecting the second upper wiring and the second conductive pad to each other;
a first lower conductive contact plug connecting the additional conductive pad and the peripheral circuit structure to each other;
a second lower conductive contact plug connecting the second conductive pad and the peripheral circuit structure to each other; and
a bonding pad disposed on a boundary between the peripheral circuit structure and the cell array structure,
wherein the first lower conductive contact plug and the second lower conductive contact plug are electrically connected to the same peripheral circuit wiring among the peripheral circuit wirings through the bonding pad.

19. The device of claim 17, wherein:
the additional conductive pad overlaps the second conductive pad in a vertical direction, with the etch stop layer disposed therebetween, and
a third peripheral sub-capacitor is configured to the second conductive pad, the additional conductive pad, and the etch stop layer.

20. The device of claim 19, wherein:
the etch stop layer comprises:
a first etch stop layer that does not overlap the first conductive pad and the second conductive pad in the vertical direction; and
a second etch stop layer that is disposed between the first conductive pad and the additional conductive pad and between the second conductive pad and the additional conductive pad, and
wherein a dielectric constant of the second etch stop layer is higher than a dielectric constant of the first etch stop layer.
